(19) United States
(12) Patent Application Publication
(10) Pub. No.: US 2019/0348415 A1
(43) Pub. Date: Nov. 14, 2019

(54) TRANSISTORS EMPLOYING CAP LAYER FOR GE-RICH SOURCE/DRAIN REGIONS

(71) Applicant: INTEL CORPORATION, Santa Clara, CA (US)

(72) Inventors: SEUNG HOON SUNG, Portland, OR (US); GLENN A. GLASS, Portland, OR (US); HAROLD W. KENNEL, Portland, OR (US); ASHISH AGRAWAL, Hillsboro, OR (US); VAN H. LE, Portland, OR (US); BENJAMIN CHU-KUNG, Portland, OR (US); SIDDHARTH CHOUKSEY, Portland, OR (US); ANAND S. MURTHY, Portland, OR (US); JACK T. KAVALIEROS, Portland, OR (US); TAHIR GHANI, Portland, OR (US)

(73) Assignee: INTEL CORPORATION, Santa Clara, CA (US)

(21) Appl. No.: 16/474,445

(22) PCT Filed: Mar. 30, 2017
(86) PCT No.: PCT/US2017/025019

§ 371 Date: Jun. 27, 2019

(51) Int. Cl. H01L 27/088; H01L 29/78; H01L 21/8234; H01L 29/417; H01L 29/40

(52) U.S. Cl. CPC H01L 27/0886; H01L 29/785; H01L 21/823431; H01L 29/401; H01L 21/823475; H01L 29/41791; H01L 21/823418

(57) ABSTRACT

Techniques are disclosed for forming transistors employing a source/drain (S/D) cap layer for Ge-rich S/D regions to, e.g., help suppress contact metal piping. Contact metal piping occurs when metal material from the S/D contact region diffuses into the channel region, which can lead to a reduction of the effective gate length and can even cause device shorting/failure. The S/D cap layer includes silicon (Si) and/or carbon (C) to help suppress the continuous reaction of contact metal material with the Ge-rich S/D material (e.g., Ge or SiGe with at least 50% Ge concentration by atomic percentage), thereby reducing or preventing the diffusion of metal from the S/D contact region into the channel region as subsequent processing occurs. In addition, the Si and/or C-based S/D cap layer is more selective to contact trench etch than the doped Ge-rich material included in the S/D region, thereby increasing controllability during contact trench etch processing.

### BACKGROUND

Semiconductor devices are electronic components that exploit the electronic properties of semiconductor materials, such as silicon, germanium, and gallium arsenide. A field-effect transistor (FET) is a semiconductor device that includes three terminals: a gate, a source, and a drain. A FET uses an electric field applied by the gate to control the electrical conductivity of a channel through which charge carriers (e.g., electrons or holes) flow from the source to the drain.

In instances where the charge carriers are electrons, the FET is referred to as an n-channel device, and in instances where the charge carriers are holes, the FET is referred to as a p-channel device. Some FETs have a fourth terminal called the body or substrate, which can be used to bias the transistor. In addition, metal-oxide-semiconductor FETs (MOSFETs) include a gate dielectric layer between the gate and the channel. MOSFETs may also be known as metal-insulator-semiconductor FETs (MISFETSs) or insulated-gate FETs (IGFETs). Complementary MOS (CMOS) structures use a combination of p-channel MOSFET (p-MOS) and n-channel MOSFET (n-MOS) to implement logic gates and other digital circuits.

A FinFET is a MOSFET transistor built around a thin strip of semiconductor material (generally referred to as a fin). The conductive channel of the FinFET device resides on the outer portions of the fin adjacent to the gate dielectric. Specifically, current runs along/within both sidewalls of the fin (sides perpendicular to the substrate surface) as well as along the top of the fin (side parallel to the substrate surface). Because the conductive channel of such configurations essentially resides along the three different outer, planar regions of the fin, such a FinFET design is sometimes referred to as a tri-gate transistor. Other types of FinFET configurations are also available, such as so-called double-gate FinFETs, in which the conductive channel principally resides only along the two sidewalls of the fin (and not along the top of the fin). A nanowire transistor (sometimes referred to as a gate-all-around (GAA) or nanoribbon transistor) is configured similarly to a fin-based transistor, but instead of a finned channel region where the gate is on three portions (and thus, there are three effective gates), one or more nanowires are used for the channel region and the gate material generally surrounds each nanowire.

### BRIEF DESCRIPTION OF THE DRAWINGS

FIG. 1 illustrates a method of forming an integrated circuit (IC) including one or more transistors employing a source/drain (S/D) cap layer for Ge-rich S/D regions, in accordance with some embodiments of the present disclosure.

FIGS. 2A-P illustrate example IC structures that are formed when carrying out the method of FIG. 1, in accordance with some embodiments.

FIG. 2H′ is a blown-out portion of FIG. 2H illustrating an alternative S/D region with a curved or rounded top, in accordance with some embodiments.

FIG. 2H″ is a blown-out portion of FIG. 2H illustrating an alternative S/D region including a cladding scheme, in accordance with some embodiments.

FIG. 3 illustrates an example cross-sectional view along the plane A-A in FIG. 2P, in accordance with some embodiments.

FIG. 4 illustrates a computing system implemented with integrated circuit structures and/or transistor devices formed using the techniques disclosed herein, in accordance with some embodiments of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles, and some features may have surface topography or otherwise be non-smooth, given real-world limitations of fabrication processes. Further still, some of the features in the drawings may include a patterned and/or shaded fill, which is merely provided to assist in visually differentiating the different features. In short, the figures are provided merely to show example structures.

### DETAILED DESCRIPTION

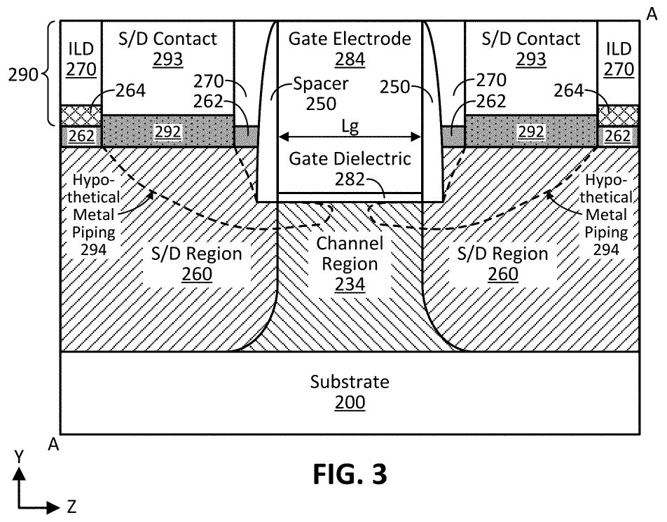

To improve upon standard transistor performance (e.g., for MOSFET devices), it is desirable in some cases to replace silicon (Si) and silicon germanium (SiGe) including relatively low germanium (Ge) concentrations (by atomic percentage) with Ge-rich materials, such as Ge or SiGe including relatively high Ge concentrations (e.g., at least 50% Ge by atomic percentage). However, replacing Si or low-concentration-Ge SiGe with Ge or high-concentration-Ge SiGe causes non-trivial issues. One such issue is that Ge-rich material has poor selectivity for the source and drain (S/D) contact trench etch, resulting in poor controllability when forming those S/D contact trenches. Another issue is that Ge-rich S/D is particularly susceptible to the formation of metal pipes during S/D contact processing, such as when using nickel (Ni) contacts, for example. Metal pipes occur when metal included in a given contact diffuses into its corresponding S/D region and down into the channel region, which leads to a reduction in the effective gate length and can even lead to electrical shorting/failure of the transistor device. For instance, hypothetical metal piping is illustrated in dashed lines in FIG. 3. This issue is exacerbated as relatively higher Ge concentrations are used in S/D material, because the germanidation of Ge occurs at relatively lower temperatures compared to the germanidation of SiGe or Si. This issue is further exacerbated for non-planar transistors (e.g., where the S/D regions are raised such that they extend above the channel region), as they provide an increased supply of Ge in which the metal piping can occur, especially as the metal continues to react with Ge in the environment caused by changes in temperature downstream in the integrated circuit (IC) fabrication flow. As a result, some research recommends using relatively lower thermal budgets when using Ge-rich S/D material to prevent metal piping. However, the relatively lower thermal budgets are not practical for standard transistor device fabrication, such as contact formation and annealing used to enable better reliability of the gate stack. In addition, the relatively lower thermal budgets are not practical for back-end-of-line (BEOL) IC processing, which may generally require temperatures of at least 400, 450, 500, 550, or 600 degrees Celsius.

Thus, and in accordance with numerous embodiments of the present disclosure, techniques are provided for forming transistors employing a source/drain (S/D) cap layer for Ge-rich S/D regions. In some embodiments, the S/D cap layer may include silicon (Si) and/or carbon (C) to help suppress the continuous reaction of contact metal with the Ge-rich S/D material (e.g., Ge or SiGe with at least 50% Ge concentration by atomic percentage), thereby reducing or preventing metal diffusion from the S/D contact region into the channel region as subsequent processing occurs. In addition, in some embodiments, the Si and/or C-based S/D cap layer is more selective to contact trench etch than the doped Ge-rich material included in the S/D region, thereby increasing controllability during contact trench etch processing. In some embodiments, the techniques include growing the S/D cap layer on one or more top surfaces of a given Ge-rich S/D region to provide the aforementioned benefits. The included component of Si and/or C in the S/D cap layer will then help suppress metal used in the contact loop processing, such as nickel (Ni), from continually reacting with the doped Ge component included in the S/D region. Further, in some embodiments, the presence of Si and/or C at the interface between a given Ge-rich S/D region and its corresponding contact need not increase contact resistance at that interface and can even lead to an improvement (reduction) in contact resistance, in some instances, depending on the particular configuration employed.

In some embodiments, a given Ge-rich S/D region may include monocrystalline Ge or SiGe (with at least 50% Ge concentration by atomic percentage) semiconductor material, as will be apparent in light of this disclosure. Further, in some embodiments, a given Ge-rich S/D region may include any suitable Ge concentration (by atomic percentage), such as Ge in the range of 50-100% (or in any suitable subrange, such as in the subrange of 50-60, 50-70, 50-80, 50-90, 60-70, 60-80, 60-90, 60-100, 70-80, 70-90, 70-100, 80-90, 80-100, or 90-100%), or any other suitable value or range as will be apparent in light of this disclosure. In some embodiments, a given Ge-rich S/D region may include a Ge concentration (by atomic percentage) of at least 50, 55, 60, 65, 70, 75, 80, 85, 90, or 95%, for example. In some embodiments, the channel region may also include Ge-rich S/D material; however, the present disclosure is not intended to be so limited unless otherwise stated. In some such embodiments, for a given transistor device, the channel region and at least one S/D region may include similar Ge concentrations (by atomic percentage), such that their Ge concentrations are within 1, 2, 3, 4, 5, or 10%, for example.

In some embodiments, the S/D cap layer includes monocrystalline group IV semiconductor material that includes at least one of Si and C. Note that the use of “group IV semiconductor material” (or “group IV material” or generally, “IV”) herein includes at least one group IV element (e.g., silicon, germanium, carbon, tin), such as silicon (Si), germanium (Ge), silicon germanium (SiGe), and so forth. Also note that the S/D cap layer may also or alternatively be referred to herein as a cladding layer or an intervening layer (e.g., as it is between the bulk Ge-rich S/D material and a corresponding contact). In embodiments employing an S/D cap layer that includes carbon, the S/D cap layer also includes a non-carbon group IV semiconductor material alloyed with the carbon (C), which is referred to herein as “Z:C”, where Z is the non-carbon group IV semiconductor material. For instance, in some such embodiments, the S/D cap layer may include Si alloyed with C, which can be represented as Si:C. Generally, in some embodiments, the cap layer may include Si, Si:C, SiGe, SiGe:C, or Ge:C. In embodiments where the S/D cap layer includes C, the included C concentration (by atomic percentage) may be in the range of 1-20% (or in a suitable subrange, such as in the subrange of 1-2, 1-5, 1-10, 2-5, 2-10, 2-20, 5-10, 5-20, or 10-20%), or any other suitable value or range as will be apparent in light of this disclosure. In some embodiments, the included C concentration (by atomic percentage) may be up to 5%. In embodiments, where the S/D cap layer includes SiGe, the Ge concentration included in the SiGe cap layer may be relatively lower than the Ge concentration included in the Ge-rich S/D material by at least 5, 10, 15, 20, 25, 30, 35, 40, 45, 50, 55, 60, 65, 70, 75, 80, 85, 90, or 95%, for example. Note that in embodiments where the S/D cap layer includes SiGe and also includes C, such that the S/D cap layer includes SiGe:C, the Ge concentration in the cap layer need not be relatively lower than the Ge concentration in the underlying S/D material, as the included C component in the cap layer can assist in suppressing metal piping (and compensate for the relatively lower Ge concentration), as can be understood based on this disclosure.

In some embodiments, the cap layer may be formed with any suitable thickness, such as a thickness in the range of 1-100 nm (or in a suitable subrange, such as 1-5, 1-10, 1-25, 1-50, 2-10, 2-25, 2-50, 2-100, 5-10, 5-25, 5-50, 5-100, 10-25, 10-50, 10-100, 25-50, 25-100, or 50-100 nm), or any other suitable value or range as will be apparent in light of this disclosure. In some embodiments, the thickness of the cap layer may be inversely related to the concentration (by atomic percentage) of Si and/or C included in the layer. For instance, in embodiments employing relatively high concentrations (by atomic percentage) of Si and/or C in the cap layer, such as C concentrations in the range of 5-20% and/or Si concentrations greater than 75%, a relatively thinner cap layer (e.g., with a thickness in the range of 2-5 nm) may be desired to assist with preventing or reducing contact metal piping, for example. Conversely, in embodiments employing relatively low concentrations (by atomic percentage) of Si and/or C in the cap layer, such as C concentrations less than 5% and/or Si concentrations less than 75%, a relatively thicker cap layer (e.g., with a thickness greater than 5 nm) may be desired to assist with preventing or reducing contact metal piping, for example. As will be apparent in light of this disclosure, during S/D contact formation, the cap layer intermixes with metal material during a germanidation and/or silicidation process, in accordance with some embodiments.

Thus, in such embodiments, the cap layer in the contact trench region is at least in part formed into a metal-semiconductor intermixed compound layer, that includes Si and/or C atoms to help suppress contact metal piping from occurring. For instance, in some embodiments, the compound layer may be considered a germanide and/or silicide layer, as it may include germanide, such as where the cap layer includes Ge and/or where a portion of the material of the Ge-rich S/D becomes a part of the intermixed compound layer, and/or it may include silicide, such as where the cap layer includes Si and/or where a portion of the material of Ge-rich S/D becomes a part of the intermixed compound layer and that Ge-rich S/D includes SiGe. To provide an example, in an embodiment where a nickel layer is deposited on a SiGe cap layer and annealed to form the metal-semiconductor compound layer, the resulting compound layer would be nickel germanosilicide (NiSiGe), where the included Si component helps suppress further diffusion of the nickel down into the S/D region (and ultimately helps suppress nickel piping from reaching the channel region). To provide another example, in an embodiment where a nickel-platinum (NiPt) layer is deposited on a SiGe cap layer and annealed to form the metal-semiconductor compound layer, the resulting compound layer would be nickel platinum germanosilicide (NiPtSiGe). In yet another example, in an embodiment where a Ni layer is deposited on a Ge:C layer and annealed to form the metal-semiconductor compound layer, the resulting compound layer would be nickel germanide (NiGe) with carbon atoms intermixed into the compound layer, where the carbon component help suppress further diffusion of the nickel down into the S/D region (and ultimately helps suppress nickel piping from reaching the channel region).

Numerous benefits of the techniques will be apparent in light of this disclosure. For instance, in some embodiments, employing an S/D cap layer as described herein improves contact trench etch selectivity/controllability and also helps to suppress contact metal diffusion into the S/D regions and the channel region, thereby preventing or reducing contact metal piping. In some embodiments, the techniques can be used to benefit a multitude of transistor devices. For instance, in some embodiments, the techniques may be used to benefit one or both of the S/D regions of a metal-oxide-semiconductor field-effect transistor (MOSFET), tunnel FET (TFET), fermi-filter FET (FFFET), and/or any other suitable transistor device, as can be understood based on this disclosure. In some embodiments, the techniques described herein can be used to benefit n-channel transistor devices (e.g., n-MOS devices) and/or p-channel transistor devices (e.g., p-MOS devices). In some embodiments, the techniques described herein can be used to benefit complementary transistor circuits, such as CMOS circuits, where the techniques employing an S/D cap layer for Ge-rich transistors may be used to benefit one or more of the included n-channel and/or p-channel transistors making up a given CMOS circuit. Further still, in some embodiments, the techniques described herein can be used to benefit transistors including a multitude of configurations, such as planar and non-planar configurations, where the non-planar configurations may include finned or FinFET configurations (e.g., dual-gate or tri-gate), gate-all-around (GAA) configurations (e.g., nanowire or nanoribbon), or some combination thereof (e.g., a beaded-fin configurations), to provide a few examples.

Note that, as used herein, the expression “X includes at least one of A and B” refers to an X that may include, for example, just A only, just B only, or both A and B. To this end, an X that includes at least one of A and B is not to be understood as an X that requires each of A and B, unless expressly so stated. For instance, the expression “X includes A and B” refers to an X that expressly includes both A and B. Moreover, this is true for any number of items greater than two, where “at least one of” those items is included in X. For example, as used herein, the expression “X includes at least one of A, B, and C” refers to an X that may include just A only, just B only, just C only, only A and B (and not C), only A and C (and not B), only B and C (and not A), or each of A, B, and C. This is true even if any of A, B, or C happens to include multiple types or variations. To this end, an X that includes at least one of A, B, and C is not to be understood as an X that requires each of A, B, and C, unless expressly so stated. For instance, the expression “X includes A, B, and C” refers to an X that expressly includes each of A, B, and C.

Use of the techniques and structures provided herein may be detectable using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDS); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may indicate an integrated circuit (IC) including at least one transistor that includes an S/D cap layer including Si and/or C as described herein. In some such embodiments, the cap layer may be converted in part or whole to a metal-semiconductor intermixed compound layer (e.g., a germanide and/or silicide layer) during S/D contact processing, such that there is a presence of Si and/or C atoms (or a relatively high presence of Si atoms) at the interface between a Ge-rich S/D region and the corresponding contact that would not be there otherwise. For instance, in some such embodiments, use of a cap layer may be detected based on Si and/or C being present at the interface between an S/D region and its corresponding contact, whether it is present as a distinct layer at the interface, or as carbon content that has dissolved into the S/D region, the contact, or both features. For example, the Si and/or C from the cap layer may become a part of the intermetallic for a given transistor source or drain, which is the location where resistance lowering metal of the contact region and semiconductor material from the cap layer (and possibly from that S/D region) react. Regardless of whether the cap layer remains a distinct layer at a given S/D region-contact interface (in other words, regardless of whether the cap layer ends up completely in the intermetallic region for a given transistor source or drain), the cap layer can be detected (e.g., via SEM/TEM) in areas outside of the contact location, such as on at least some portions of a given S/D region in areas outside of where the contact trench accessed the given S/D region, in accordance with some embodiments. In some embodiments, the techniques and structures described herein may be detected based on the benefits derived therefrom, such as the reduction or elimination of contact metal (e.g., Ni) piping for Ge-rich S/D regions. Numerous configurations and variations will be apparent in light of this disclosure.

Architecture and Methodology

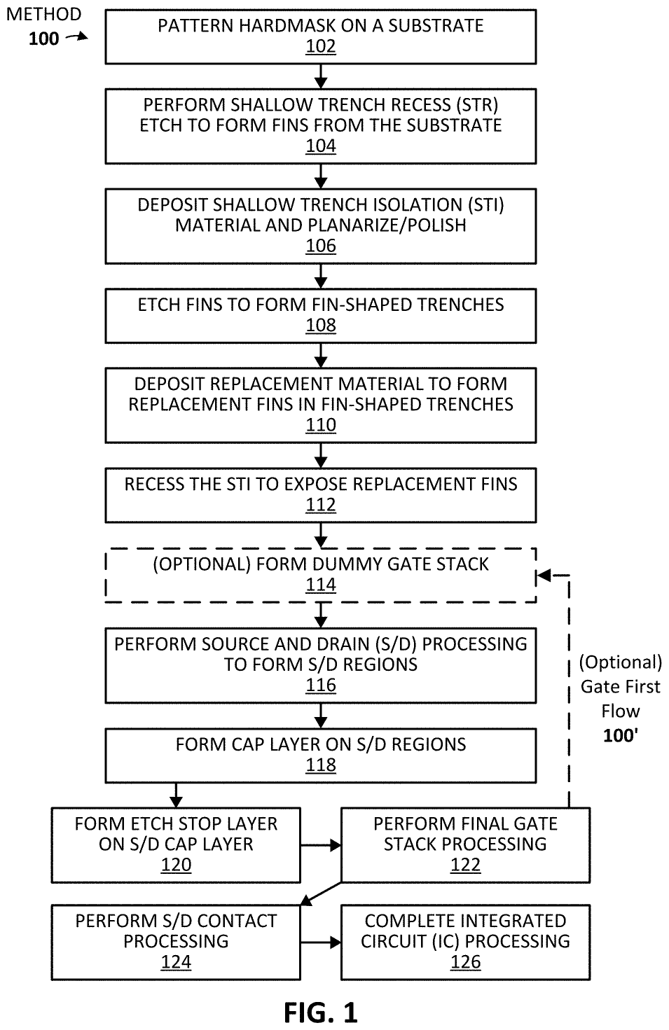

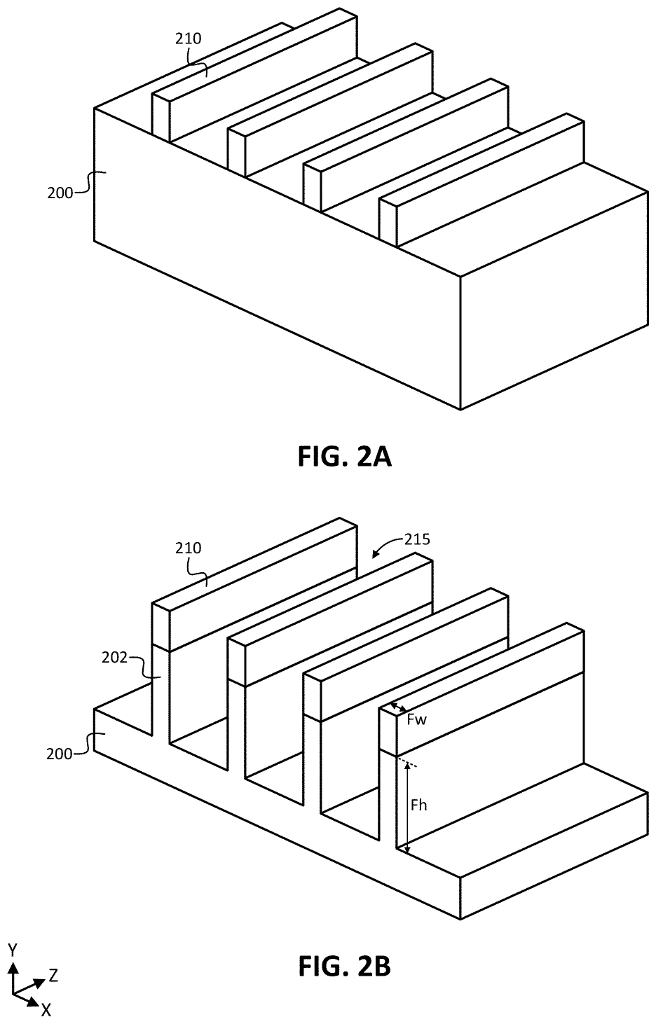

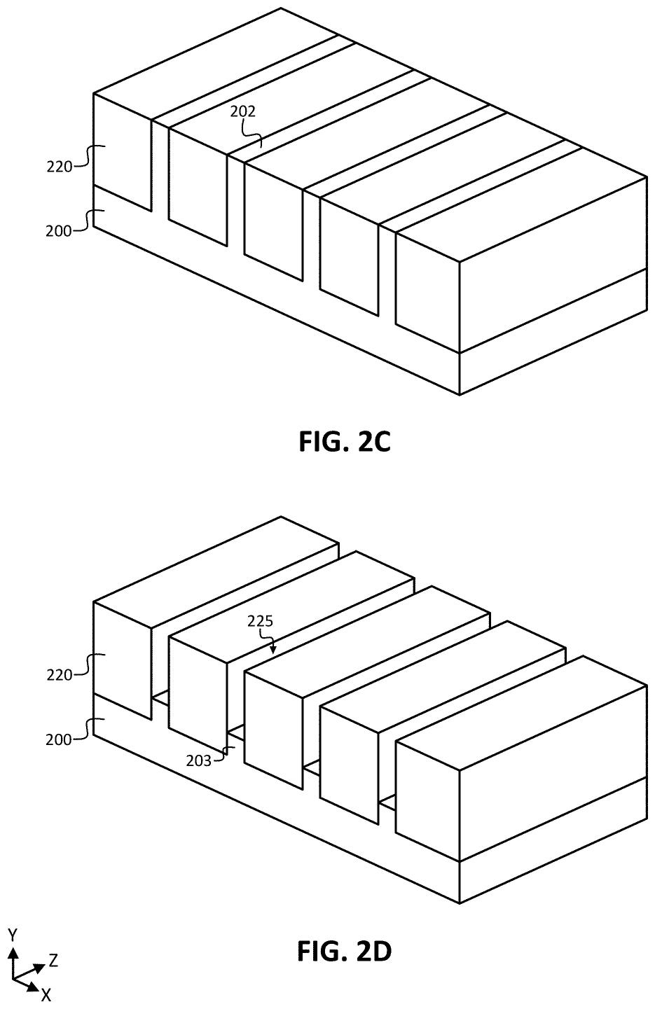

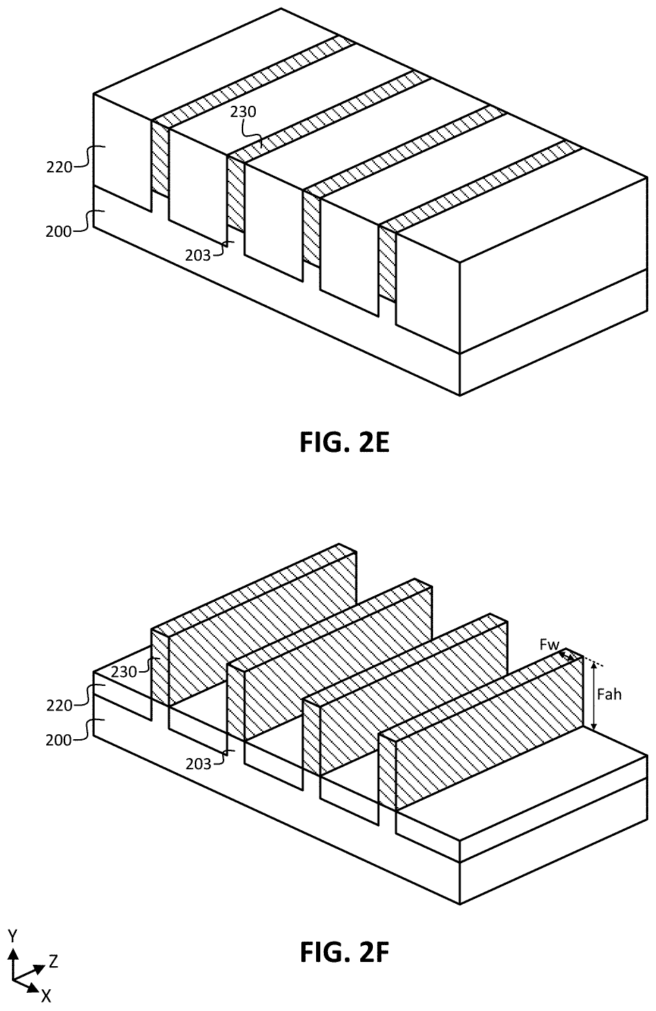

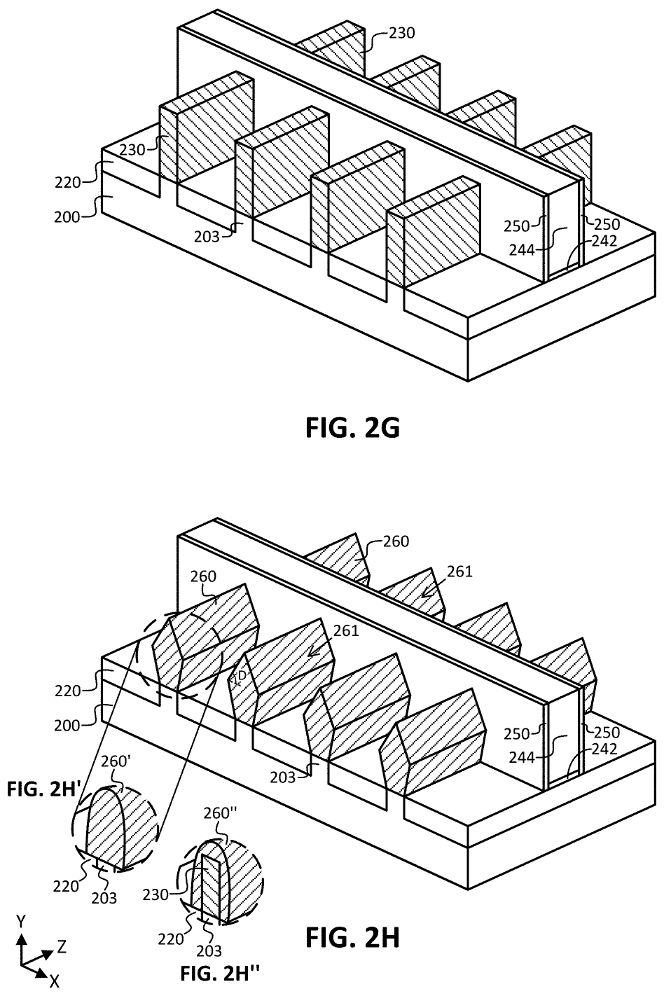

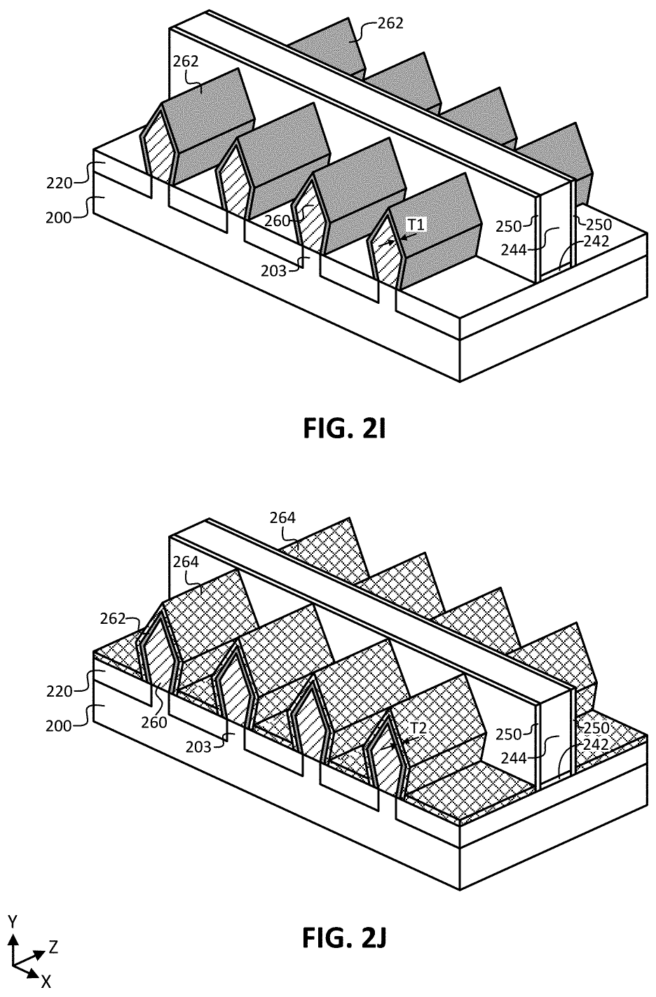

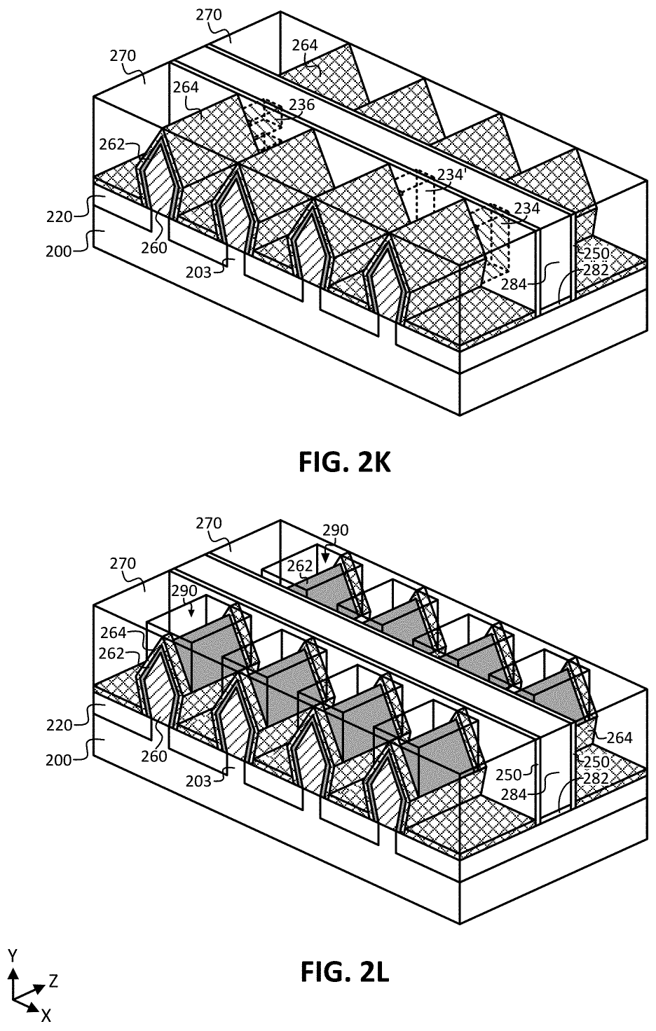

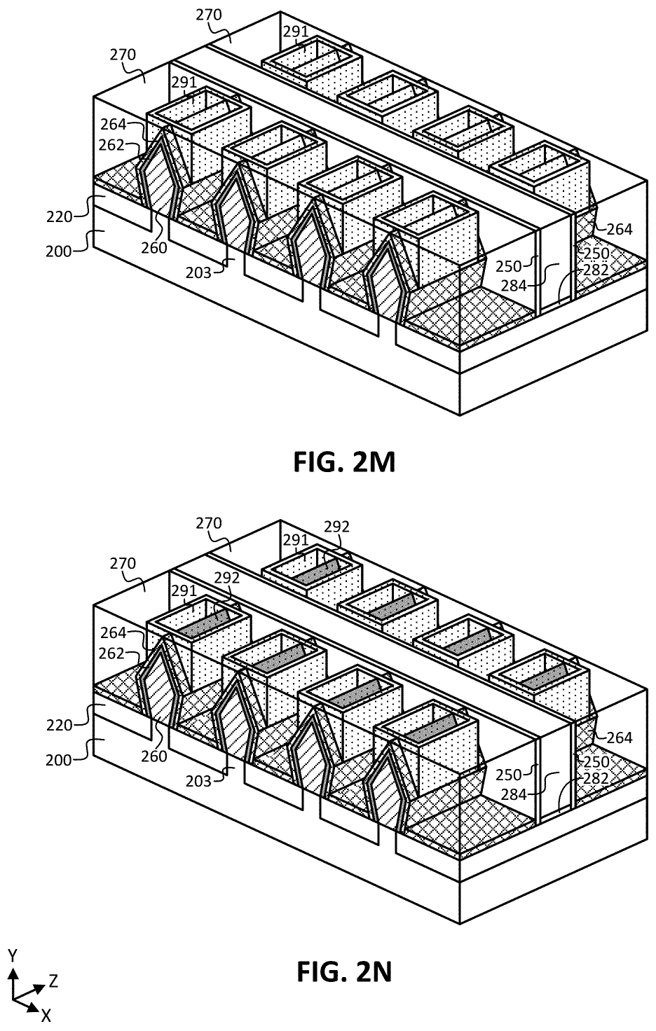

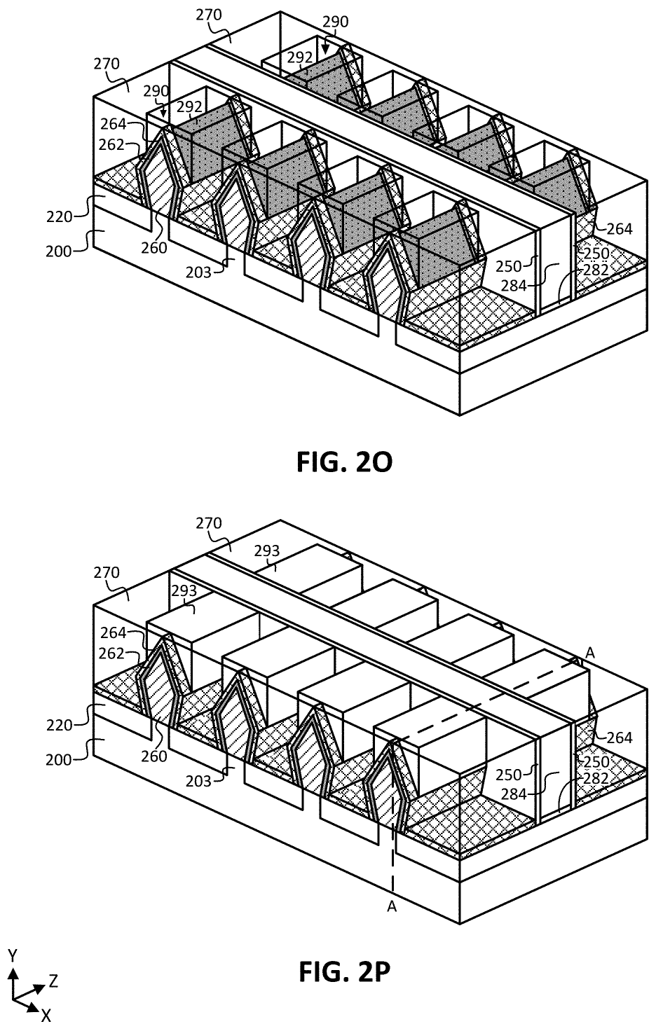

FIG. 1 illustrates method 100 of forming an integrated circuit (IC) including one or more transistors employing a source/drain (S/D) cap layer for Ge-rich S/D regions, in accordance with some embodiments of the present disclosure. FIGS. 2A-P illustrate example IC structures that are formed when carrying out method 100 of FIG. 1, in accordance with some embodiments. Note that method 100 includes a primary path that illustrates a gate last transistor fabrication process flow (e.g., a replacement gate or replacement metal gate (RMG) process flow), in accordance with some embodiments. However, in other embodiments, a gate first process flow may be used, as will be described herein (and which is illustrated with the alternative gate first flow 100′ indicator in FIG. 1). The structures of FIGS. 2A-P are primarily depicted and described herein in the context of forming finned or FinFET transistor configurations (e.g., tri-gate transistor configurations), for ease of illustration. However, in some embodiments, the techniques can be used to form transistors of any suitable geometry or configuration, as can be understood based on this disclosure. For example, FIG. 2K illustrates an example IC structure including a transistor with a nanowire configuration, as will be described in more detail below. Numerous variations and configurations will be apparent in light of this disclosure.

A multitude of different transistor devices can benefit from the techniques described herein, which includes, but is not limited to, various field-effect transistors (FETs), such as metal-oxide-semiconductor FETs (MOSFETs), tunnel FETs (TFETs), and Fermi filter FETs (FFFETs), to name a few examples. For example, the techniques may be used to benefit either or both of the S/D regions of an n-channel MOSFET (n-MOS) device, which may include a source-channel-drain doping scheme of n-p-n or n-i-n, where ‘n’ indicates n-type doped semiconductor material, ‘p’ indicates p-type doped semiconductor material, and ‘i’ indicates intrinsic/undoped semiconductor material (which may also include nominally undoped semiconductor material, including dopant concentrations of less than 1E16 atoms per cubic centimeter (cm), for example), in accordance with some embodiments. In another example, the techniques may be used to benefit either or both of the S/D regions of a p-channel MOSFET (p-MOS) device, which may include a source-channel-drain doping scheme of p-n-p or p-i-p, in accordance with some embodiments. In yet another example, the techniques may be used to benefit either or both of the S/D regions of a TFET device, which may include a source-channel-drain doping scheme of p-i-n or n-i-p, in accordance with some embodiments. In still another example, the techniques may be used to benefit one or both of the S/D regions of a FFFET device, which may include a source-channel-drain doping scheme of np-i-p (or np-n-p) or pn-i-n (or pn-p-n), in accordance with some embodiments. Further, the techniques may be used to benefit complementary transistor circuits, such as CMOS circuits, where the techniques may be used to benefit one or more of the included n-channel and/or p-channel transistors making up the CMOS circuit. Other example transistor devices that can benefit from the techniques described herein include few to single electron quantum transistor devices, in accordance with some embodiments. Further still, any such devices may employ semiconductor materials that are three-dimensional crystals as well as two dimensional crystals or nanotubes, for example. In some embodiments, the techniques may be used to benefit devices of varying scales, such as IC devices having critical dimensions in the micrometer (micron) range and/or in the nanometer (nm) range (e.g., formed at the 22, 14, 10, 7, 5, or 3 nm process nodes, or beyond).

Method 100 of FIG. 1 includes patterning 102 hardmask on a substrate, such as patterning hardmask 210 on substrate 200 to form the example resulting structure of FIG. 2A, in accordance with some embodiments. In some embodiments, hardmask 210 may be deposited or otherwise formed on substrate 200 using any suitable techniques as will be apparent in light of this disclosure. For example, hardmask 210 may be blanket deposited or otherwise grown on substrate 200 using chemical vapor deposition (CVD), atomic layer deposition (ALD), physical vapor deposition (PVD), spin-on processing, and/or any other suitable process. In some instances, the top surface of substrate 200 on which hardmask 210 is to be deposited may be treated (e.g., via chemical treatment, thermal treatment, etc.) prior to deposition of the hardmask 210 material. After being blanket formed on substrate 200, hardmask 210 may then be patterned using any suitable techniques, such as one or more lithography and etch processes, for example. Hardmask 210 may include any suitable material, such as oxide material, nitride material, dielectric material, and/or any other electrical insulator material, for example. Specific oxide and nitride materials may include silicon oxide, titanium oxide, hafnium oxide, aluminum oxide, silicon nitride, and titanium nitride, just to name a few examples. In some cases, the material of hardmask 210 may be selected based on the material of substrate 200, for example.

Substrate 200, in some embodiments, may include: a bulk substrate including group IV semiconductor material, such as silicon (Si), germanium (Ge), silicon germanium (SiGe), and/or group III-V material and/or any other suitable semiconductor material(s) as will be apparent in light of this disclosure; an X on insulator (XOI) structure where X is one of the aforementioned semiconductor materials (e.g., group IV and/or group III-V semiconductor material) and the insulator material is an oxide material or some other dielectric/electric insulator material; or some other suitable multilayer structure where the top layer includes one of the aforementioned semiconductor materials (e.g., group IV and/or group III-V semiconductor material). The use of “group IV semiconductor material” (or “group IV material” or generally, “IV”) herein includes at least one group IV element (e.g., silicon, germanium, carbon, tin), such as silicon (Si), germanium (Ge), silicon germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), and so forth. Note that group III may also be known as the boron group or IUPAC group 13, group IV may also be known as the carbon group or IUPAC group 14, and group V may also be known as the nitrogen family or IUPAC group 15, for example.

In some embodiments, substrate 200 may be doped with any suitable n-type and/or p-type dopant. For instance, in the case, of a Si substrate, the Si may be p-type doped using a suitable acceptor (e.g., boron) or n-type doped using a suitable donor (e.g., phosphorous, arsenic), to provide some example cases. Such dopants are generally applicable to any group IV semiconductor material, such as Si, SiGe and Ge. However, in some embodiments, substrate 200 may be undoped/intrinsic or relatively minimally doped (such as including a dopant concentration of less than 1E16 atoms per cubic centimeter (cm)), for example. In some embodiments, substrate 200 may include a surface crystalline orientation described by a Miller index of (100), (110), or (111), or its equivalents, as will be apparent in light of this disclosure.

Although substrate 200, in this example embodiment, is shown as having a thickness (dimension in the Y-axis direction) similar to other layers shown in subsequent structures for ease of illustration, in some instances, substrate 200 may be relatively much thicker than the other layers, such as having a thickness in the range of 50 to 950 microns, for example, or any other suitable thickness as will be apparent in light of this disclosure. In some embodiments, substrate 200 may be used for one or more other IC devices, such as various diodes (e.g., light-emitting diodes (LEDs) or laser diodes), various transistors (e.g., MOSFETs or TFETs), various capacitors (e.g., MOSCAPs), various microelectromechanical systems (MEMS), various nanoelectromechanical systems (NEMS), various radio frequency (RF) devices, various sensors, or any other suitable semiconductor or IC devices, depending on the end use or target application. Accordingly, in some embodiments, the structures described herein may be included in a system-on-chip (SoC) application, as will be apparent in light of this disclosure.

Method 100 of FIG. 1 continues with performing 104 shallow trench recess (STR) etch to form fins 202 from substrate 200, thereby forming the resulting example structure shown in FIG. 2B, in accordance with some embodiments. In some embodiments, the STR etch 104 used to form trenches 215 and fins 202 may include any suitable techniques, such as various masking processes and wet and/or dry etching processes, for example. In some cases, STR etch 104 may be performed in-situ/without air break, while in other cases, STR etch 104 may be performed ex-situ, for example. Trenches 215 may be formed with varying widths (dimension in the X-axis direction) and depths (dimension in the Y-axis direction) as can be understood based on this disclosure. For example, multiple hardmask patterning 102 and STR etching 104 processes may be performed to achieve varying depths in the trenches 215 between fins 202. Fins 202 may be formed to have varying widths Fw (dimension in the X-axis direction) and/or heights Fh (dimension in the Y-axis direction). Note that although hardmask structures 210 are still present in the example structure of FIG. 2B, in some cases, that need not be the case, as they may have been consumed during the STR etch, for example.

In some embodiments, the fin widths Fw (dimension in the horizontal or X-axis direction) may be in the range of 2-400 nm (or in a subrange of 2-10, 2-20, 2-50, 2-100, 2-200, 4-10, 4-20, 4-50, 4-100, 4-200, 4-400, 10-20, 10-50, 10-100, 10-200, 1-400, 50-100, 50-200, 50-400, or 100-400 nm), for example, or any other suitable value or range as will be apparent in light of this disclosure. In some embodiments, the fin heights Fh (dimension in the vertical or Y-axis direction) may be in the range of 4-800 nm (or in a subrange of 4-10, 4-20, 4-50, 4-100, 4-200, 4-400, 10-20, 10-50, 10-100, 10-200, 10-400, 10-800, 50-100, 50-200, 50-400, 50-800, 100-400, 100-800, or 400-800 nm), for example, or any other suitable value or range as will be apparent in light of this disclosure. In some embodiments, the fin heights Fh may be at least 25, 50, 75, 100, 125, 150, 175, 200, 300, 400, or 500, 600, 700, or 800 nm tall, or greater than any other suitable threshold height as will be apparent in light of this disclosure. In some embodiments, the height to width ratio of the fins (Fh:Fw) may be greater than 1, such as greater than 1.5, 2, 2.5, 3, 3.5, 4, 4.5, 5, 6, 7, 8, 9, or 10, or greater than any other suitable threshold ratio, as will be apparent in light of this disclosure. Note that the trenches 215 and fins 202 are each shown as having essentially the same sizes and shapes in this example structure for ease of illustration; however, the present disclosure is not intended to be so limited. For example, in some embodiments, the fins 202 may be formed to have varying heights Fh, varying widths Fw, varying starting points (or varying starting heights), varying shapes, and/or any other suitable variations as will be apparent in light of this disclosure. Moreover, trenches 215 may be formed to have varying depths, varying widths, varying starting points (or varying starting depths), varying shapes, and/or any other suitable variations as will be apparent in light of this disclosure. Further note that although four fins 202 are shown in the example structure of FIG. 2B for ease of illustration, any number of fins may be formed, such as one, two, three, five, ten, hundreds, thousands, millions, billions, and so forth, as can be understood based on this disclosure.

In embodiments employing an aspect ratio trapping (ART) integration scheme, fins 202 may be formed to have particular height to width ratios such that if they are later removed or recessed, the resulting fin-shaped trenches formed allow for defects in the replacement material deposited to terminate on a side surface as the material grows vertically, such as non-crystalline/dielectric sidewalls, where the sidewalls are sufficiently high relative to the size of the growth area so as to trap most, if not all, of the defects, if such an ART scheme is used. In some such embodiments employing an ART scheme, the fins may be formed to have particular height to width ratios such that when they are later recessed and/or removed, the resulting fin trenches formed allow for defects in the replacement material deposited to terminate on a side surface as the material grows vertically, such as non-crystalline/dielectric sidewalls, where the sidewalls are sufficiently high relative to the size of the growth area so as to trap most, if not all, of the defects. Generally, in a trench fill integration scheme, the fins may be formed to have particular height to width ratios such that when they are later removed or recessed, the resulting trenches formed allow the replacement material deposited to grow vertically from the native substrate bottom and be confined by non-crystalline/dielectric sidewalls. The material used to fill these trenches may be sufficiently lattice matched to the substrate (or to a buffer layer used between the substrate and replacement material) such that effectively no relaxation or threading misfit dislocation formation occurs (e.g., the misfit dislocations occur at levels below 1E5 dislocations per square cm). For instance, this lattice match condition is true for native Si fins and trench fill of SiGe replacement material having Ge concentration (by atomic percentage) of less than 45% and fin heights Fh of less than 50 nm, to provide an example. Alternatively, using the Si substrate example (where the native Si fins are recessed to form trenches), a replacement material trench fill of Ge or SiGe with Ge concentration of at least 80% can be performed such that the dislocations form right at the native/replacement material interface and again effectively no threading misfit dislocation formation occurs at the top surface of the replacement material fin (e.g., the misfit dislocations occur at levels below 1E5 dislocations per square cm).

Method 100 of FIG. 1 continues with depositing 106 shallow trench isolation (STI) material 220 and planarizing/polishing the structure to form the example resulting structure of FIG. 2C, in accordance with some embodiments. In some embodiments, deposition 106 of STI material 220 may include any suitable deposition techniques, such as those described herein (e.g., CVD, ALD, PVD), or any other suitable deposition process. In some embodiments, STI material 220 (which may be referred to as an STI layer) may include any suitable electrical insulator material, such as one or more dielectric, oxide (e.g., silicon dioxide), and/or nitride (e.g., silicon nitride) materials. In some embodiments, the material of STI layer 220 may be selected based on the material of substrate 200. For instance, in the case of a Si substrate, the STI material may be selected from silicon dioxide or silicon nitride, to provide some examples. In some embodiments, the planarizing and/or polishing process(es) performed after forming STI material 220 may include any suitable techniques, such as chemical-mechanical planarization/polishing (CMP) processes, for example.

Method 100 of FIG. 1 continues with etching 108 fins 202 to form fin-shaped trenches 225 between the STI material 220 as shown in the resulting example structure of FIG. 2D, in accordance with some embodiments. In some embodiments, etching 108 may be performed using any suitable techniques, such as one or more wet and/or dry etch processes that selectively removes/recesses the material of fins 202 relative to the STI material 220 to form fin-shaped trenches 225, and/or any other suitable processing as will be apparent in light of this disclosure. As shown in the example embodiment of FIG. 2D, a sub-fin portion 203 from fins 202 remains below fin-shaped trenches 225, where the vertical height (dimension in the Y-axis direction) of the sub-fin portion 203 may be based on the etch processing 108 used to form fin-shaped trenches 225. For example, in some embodiments, the etch processing 108 may be performed with characteristics (e.g., a longer etch duration) that removes relatively more of fins 202, such that a shorter (by vertical height) sub-fin portion 203 may remain or the fins 202 may be completely removed, such that the fin-shaped trenches 225 extend to the bottom of STI material 220 and possibly beyond. However, in other embodiments, the etch processing 108 may be performed with characteristics (e.g., a shorter etch duration) that removes relatively less of fins 202, such that a taller (by height) sub-fin portion 203 may remain. Regardless, fin-shaped trenches 225 may have similar (or the same) widths (dimension in the X-axis direction) as the width (Fw) of fins 202 that were removed and similar (or the same) depths (dimension in the Y-axis direction) as the height (Fh) of fins 202 that were removed, in accordance with some embodiments.

Method 100 of FIG. 1 continues with depositing 110 replacement material to form replacement material fins 230 in fin-shaped trenches 225, thereby forming the example resulting structure of FIG. 2E, in accordance with some embodiments. In some such embodiments, deposition 110 of the replacement material may include any suitable techniques, such as CVD, PVD, ALD, molecular beam epitaxy (MBE), and/or any other suitable process as can be understood based on this disclosure. As can also be understood based on this disclosure, in some embodiments, deposition processing 110 may be followed by planarization/polish processing (e.g., via CMP) to form the structure of FIG. 2E, in accordance with some embodiments. As can further be understood based on this disclosure, replacement material fins 230 may be used in the channel region(s) of one or more transistors, such that the material of fins 230 may also include material included in those channel regions.

Note that in the example embodiment of FIG. 2E, all native fins 202 were removed and replaced with replacement material fins 230. However, in other embodiments, such processing need not occur at all, such that the method continues by using the native fins. In embodiments where one or more native fins 202 are replaced, all of the native fins 202 may be replaced or only a subset may be replaced (e.g., such that some replacement fins 230 are available for subsequent processing and some native fins 202 remain for subsequent processing). Further, in some embodiments, the recess and replace process may be performed as many times as desired to form as many subsets of replacement fins as desired by masking off the areas not to be processes for each replacement fin subset processing. In some such embodiments, a first subset of replacement fins may be formed for n-channel transistors and a second subset of replacement fins may be formed for p-channel transistors, for example. Further still, in some embodiments, a multilayer replacement fin may be formed to enable the subsequent formation of nanowires or nanoribbons in the channel region of one or more transistors, where some of the layers in the multilayer replacement fin are sacrificial and intended to be removed via selective etching (e.g., during replacement gate processing), which will be described in more detail herein.

In some embodiments, replacement material fins 230 may include any suitable semiconductor material as will be apparent in light of this disclosure, such as group IV semiconductor material. In some such embodiments, replacement material fins 230 may include Ge-rich material, such as Ge or SiGe with at least 50% Ge concentration (by atomic percentage). Thus, in such embodiments where the replacement material fins 230 include Ge-rich material, the Ge concentration may be in the range of 50-100% (or in any suitable subrange, such as in the subrange of 50-60, 50-70, 50-80, 50-90, 60-70, 60-80, 60-90, 60-100, 70-80, 70-90, 70-100, 80-90, 80-100, or 90-100%), or any other suitable value or range as will be apparent in light of this disclosure. In some embodiments, replacement material fins 230 may include a Ge concentration (by atomic percentage) of at least 50, 55, 60, 65, 70, 75, 80, 85, 90, or 95%, for example. In some embodiments, replacement material fins 230 may include semiconductor material that is intrinsic/undoped (or nominally undoped with a dopant concentration of less than 1E16 atoms per cubic cm), n-type doped, p-type doped, or some combination thereof (e.g., doped in some portions and undoped in other portions, or n-type doped in some portions but p-type doped in other portions). In embodiments where dopant is included in the semiconductor material of replacement fins 230, or generally, in any semiconductor material described herein, it may be introduced using any suitable techniques, such as via ion implantation and/or depositing the dopants with the bulk semiconductor material, for example. In some embodiments, replacement material fins 230 may include grading (e.g., increasing and/or decreasing) of the concentration of one or more materials within the features, such as the grading of the Ge concentration and/or the grading of the dopant concentration, for example. In some embodiments, replacement material fins 230 may include a multilayer structure that includes at least two distinct layers. For example, in embodiments employed to form a nanowire transistor, a given replacement material fin may include at least one layer to be formed into at least one nanowire in the channel region of the transistor and at least one sacrificial layer (which may alternate with the at least one nanowire layer) to be selectively etched and removed to release the at least one nanowire layer, as can be understood based on this disclosure. Note that the replacement material fins 230 are all shown as including the same material, in the example structure of FIG. 2E, for ease of illustration; however, the present disclosure is not intended to be so limited.

Method 100 of FIG. 1 continues with recessing 112 the STI material 220 to form the example resulting structure of FIG. 2F, in accordance with some embodiments. In some embodiments, recessing 112 may be performed using any suitable techniques, such as one or more wet and/or dry etch processes that allow the STI material 220 to be selectively recessed relative to the replacement fin 230 material, and/or any other suitable processing as will be apparent in light of this disclosure. As shown in FIG. 2F, the recessing 112 allows replacement material fins 230 to exude from the STI material 220 (and more specifically, from the top plane of STI layer 220), for example. As is also shown, sub-fin portions 203 (that are native to substrate 200, in this example embodiment) are below the top plane of STI layer 220. Note that in this example embodiment, the top plane of STI layer 220 is exactly at the level of the interface between replacement fins 230 and sub-fin portions 203; however, the present disclosure is not intended to be so limited. For instance, STI material 220 may have been recessed more or less, in other embodiments, such that a portion of replacement material fins 230 may be included in the sub-fin or sub-channel region (the region below the channel region) or a portion of the current native sub-fin 203 may be included in the channel region, for example.

In this example embodiment, the width (dimension in the X-axis direction) of replacement material fins 230 is the same as the width of fins 202 (i.e., width Fw) previously described. However, the height (dimension in the Y-axis direction) of replacement material fins 230 is less than the height of fins 202 (i.e., height Fh). Instead, the height of the replacement material fins 230 may be referred to as the active fin height Fah, as that height of a given fin 230 may be used in the channel region of a transistor formed therefrom, in accordance with some embodiments. In some embodiments, the height of replacement material fins 230, or more generally, the active fin height (to be used in the channel region of a given transistor), which is shown as Fah, may be in the range of 4-800 nm (or in a subrange of 4-10, 4-20, 4-50, 4-100, 4-200, 4-400, 10-20, 10-50, 10-100, 10-200, 10-400, 10-800, 50-100, 50-200, 50-400, 50-800, 100-400, 100-800, or 400-800 nm), for example, or any other suitable value or range as will be apparent in light of this disclosure. In some embodiments, the active fin heights Fah may be at least 25, 50, 75, 100, 125, 150, 175, 200, 300, 400, or 500, 600, 700, or 800 nm tall, or greater than any other suitable threshold height as will be apparent in light of this disclosure. In some embodiments, the height to width ratio of the active fin (Fah:Fw) may be greater than 1, such as greater than 1.5, 2, 2.5, 3, 3.5, 4, 4.5, 5, 6, 7, 8, 9, or 10, or greater than any other suitable threshold ratio, as will be apparent in light of this disclosure. In some embodiments, the replacement material fins 230 of the example structure of FIG. 2F may be formed using alternative processing (as opposed to the replacement fin scheme described herein with reference to FIGS. 2A-F). For instance, in some embodiments, replacement material fins 230 may be formed using by blanket-growing/depositing the replacement material on the substrate and then patterning the replacement material into replacement material fins, to provide an example alternative. In such alternative processing, STI material may then be deposited, planarized/polished, and recessed as previously described to form the structure of FIG. 2F, for example (however, note that native sub-fin portions 203 may not be present).

Method 100 of FIG. 1 continues with optionally forming 114 a dummy gate stack to form the example resulting structure of FIG. 2G, in accordance with some embodiments. Recall that method 100 is primarily described herein in the context of a gate last transistor fabrication process flow, where the processing includes forming a dummy gate stack, performing the S/D processing, and then forming the final gate stack after the S/D regions have been processed. However, in other embodiments, the techniques may be performed using a gate first process flow. In such an example case, process 114 (forming a dummy gate stack) would not be performed, and thus, process 114 is optional in some embodiments (such as those employing the gate first process flow). This is reflected with the alternative location for performing 122 final gate stack processing, which is shown as the optional gate first flow 100′ in FIG. 1, where performing 122 the final gate stack processing would instead occur at the location of box 114, for example. However, the description of method 100 will continue using a gate last process flow, to allow for such a flow (which generally includes additional processing) to be adequately described.

Continuing with forming 114 a dummy gate stack, such a dummy gate stack (where employed) may include dummy gate dielectric 242 and dummy gate electrode 244, thereby forming the example resulting structure of FIG. 2G, in this example embodiment. Dummy gate dielectric 242 (e.g., dummy oxide material) and dummy gate or dummy gate electrode 244 (e.g., dummy poly-silicon material) may be used for a replacement gate process, as can be understood based on this disclosure. Note that side-wall spacers 250, referred to generally as gate spacers (or simply, spacers), on either side of the dummy gate stack were also formed, and such spacers 250 can help determine the channel length and can help with replacement gate processes, for example. As can be understood based on this disclosure, the dummy gate stack (and spacers 250) help define the channel region and source/drain (S/D) regions of each fin, where the channel region is below the dummy gate stack (as it will be located below the final gate stack), and the S/D regions are on either side of and adjacent to the channel region. Note that because the IC structures are being described in the context of forming finned transistors, the final gate stack will also be adjacent to either side of the fin, as the gate stack will reside along three walls of the finned channel regions, in some embodiments. Formation of the dummy gate stack may include depositing the dummy gate dielectric material 242 and dummy gate electrode material 244, patterning the dummy gate stack, depositing gate spacer material 250, and performing a spacer etch to form the structure shown in FIG. 2G, for example. Spacers 250 may include any suitable material, such as any suitable electrical insulator, dielectric, oxide (e.g., silicon oxide), and/or nitride (e.g., silicon nitride) material, as will be apparent in light of this disclosure. Note that in some embodiments, as previously described, the techniques described herein need not include forming a dummy gate stack, such that a final gate stack may be formed in the first instance. Regardless, with either a gate last or a gate first process flow, the end structure will include the final gate stack which is described in more detail below, as will be apparent in light of this disclosure. Also note that in some embodiments, a hardmask (not shown) may be formed over the dummy gate stack (which may also be formed over spacers 250) to, e.g., protect the dummy gate stack during subsequent processing.

Method 100 of FIG. 1 continues with performing 116 source/drain (S/D) processing to form final S/D regions 260 in the example resulting structure of FIG. 2H, in accordance with some embodiments. In some embodiments, S/D processing 116 may include any suitable techniques, such as removing replacement fins 230 in the S/D regions (regions not covered by the dummy gate stack) and replacing them with final S/D regions 260 by selectively depositing the final S/D material 260 such that it only significantly forms from the top seeding surface of sub-fin portion 203, to provide an example. In such embodiments, the portions of replacement fins 230 (or native fins, in embodiments retaining native fins) in the S/D regions may be removed using any suitable wet and/or dry etch processes. Further, in some such embodiments, depositing the final S/D material 260 may include any suitable techniques, such as one or more of the depositions processes described herein (e.g., CVD, ALD, PVD, MBE), and/or any other suitable processes as will be apparent in light of this disclosure. In some such embodiments, the replacement S/D regions 260 may be formed using a selective deposition process, e.g., such that the S/D material only or significantly grows (or only grows in a monocrystalline structure) from the exposed semiconductor material sub-fin portions 203, as can be understood based on this disclosure.

Note that the S/D regions 260 are referred to herein as such for ease of description, but a given S/D region 260 may be either a source region or a drain region, such that a corresponding pair of S/D regions 260 for a given transistor are formed along the same fin and on either side of the dummy gate stack, in this example embodiment. As shown in FIG. 2H, the S/D regions 260 each include {111} faceting on the two top surfaces 261, for example. However, the present disclosure is not intended to be so limited. In some embodiments, a {111} faceted surface 261 of a given S/D region 260 may be represented by that surface including an angle (illustrated in FIG. 2H as angle D) of approximately 54.7 degrees (plus/minus 5 degrees) relative to the (001) plane, the main plane of substrate 200, the top plane of substrate 200, and/or the top plane of STI layer 220, for example. In other words, in some embodiments, the S/D regions 260 may be considered to be approximately diamond-shaped, where the {111} faceted shape of the S/D regions 260 may be considered to be approximately pyramid-shaped, for example. However, other S/D region shapes and configurations may be employed. For instance, FIG. 2H′ is a blown-out portion of FIG. 2H illustrating an alternative S/D region 260′ with a curved or rounded top, in accordance with some embodiments. Thus, a given S/D region may have a multitude of different shapes and sizes. In addition, in some embodiments, replacement fins 230 (or native fins 202, where kept for subsequent processing) may be retained in the S/D regions, where additional S/D material is deposited thereon to form the final S/D regions, for example. For instance, FIG. 2H″ is a blown-out portion of FIG. 2H illustrating an alternative S/D region including a cladding scheme, in accordance with some embodiments. As can be understood based on FIG. 2H″, final S/D material 260″ is grown as a cladding layer on a replacement fin 230, such that the replacement fin is retained in that alternative S/D region. The relevant discussion of S/D material 260 herein is equally applicable to S/D material 260′ and 260″.

In some embodiments, a given S/D region 260 may include any suitable semiconductor material as will be apparent in light of this disclosure, such as monocrystalline (or single-crystal) group IV and/or group III-V semiconductor material. In some such embodiments, a given S/D region 260 may include Ge-rich material, such as Ge or SiGe with at least 50% Ge concentration (by atomic percentage). Thus, in such embodiments where a given S/D region includes Ge-rich material, the Ge concentration may be in the range of 50-100% (or in any suitable subrange, such as in the subrange of 50-60, 50-70, 50-80, 50-90, 60-70, 60-80, 60-90, 60-100, 70-80, 70-90, 70-100, 80-90, 80-100, or 90-100%), or any other suitable value or range as will be apparent in light of this disclosure. In some embodiments, a given S/D region may include a Ge concentration (by atomic percentage) of at least 50, 55, 60, 65, 70, 75, 80, 85, 90, or 95%, for example. In some embodiments, S/D regions 260 may include semiconductor material that is n-type doped and/or p-type doped. In some embodiments, a given S/D 260 region may include grading (e.g., increasing and/or decreasing) of the concentration of one or more materials within the features, such as the grading of the Ge concentration and/or the grading of the dopant concentration, for example. For instance, in some such embodiments, the dopant concentration included in a given S/D region may be graded such that it is lower near the corresponding channel region and higher near the corresponding S/D contact, which may be achieved using any suitable processing, such as tuning the amount of dopant in the reactant flow (e.g., during an in-situ doping scheme). In some embodiments, a given S/D region may include a multilayer structure that includes at least two compositionally different material layers.

Note that the S/D regions 260 are shown with different patterning than replacement fins 230 to assist with visual identification of the different features in the figures. However, the patterning/shading of any of the features in the figures is not intended to limit the present disclosure in any manner and is merely provided to assist with visual identification of the different features described herein. Also note that S/D regions 260 are all shown as including the same material and sizes/shapes in the example structure of FIG. 2H, for ease of illustration; however, the present disclosure is not intended to be so limited. For example, in some embodiments, one of the S/D regions may be processed separately than the other S/D regions, such that a corresponding S/D pair may include different material, dopant type, and/or dopant concentration. For instance, in the case of a TFET device, one of the S/D regions may include n-type doped semiconductor material and the other of the S/D regions may include p-type doped semiconductor material, to provide an example case. Such differences in processing may be achieved by masking off the source region to process the drain region, and then masking off the drain region to process the source region, for example. In some embodiments, a given S/D region may include the same or similar (e.g., with 1-3%) Ge concentration as the corresponding/adjacent channel region (which may be determined based on the material of replacement fins 230). However, in other embodiments, a given S/D region may include relatively different Ge concentration (e.g., at least 3, 5, or 10% different) compared to a corresponding/adjacent channel region, for example. Further note that each of the S/D regions 260 are raised S/D regions, such that the material of the regions extends to a level that is above the channel region (e.g., such that the material is adjacent the gate structure, with insulator spacers between the raised S/D and the gate structure).

Method 100 of FIG. 1 continues with forming 118 cap layer 262 on the S/D regions 260 of the structure of FIG. 2H to form the resulting example structure of FIG. 21, in accordance with some embodiments. In some embodiments, the cap layer 262 may be formed on the S/D regions 260 using any suitable techniques, such as using one or more deposition processes described herein (e.g., CVD, ALD, PVD, MBE), and/or any other suitable processes as will be apparent in light of this disclosure. In some embodiments, the cap layer 262 may be selectively deposited on the semiconductor material included in the S/D regions such that it only or significantly forms from that semiconductor material using any suitable selective deposition process. As shown in the example structure of FIG. 21, the cap layer 262 was formed over the entirety of each S/D region 260, such that the cap layer 262 may be considered a cladding layer, in this example embodiment. However, the present disclosure is not intended to be so limited, unless otherwise stated. For instance, in other embodiments, the cap layer 262 may only form on the top surfaces of the S/D regions. Note that although the cap layer 262 was formed on both of the corresponding S/D regions for each of the four S/D region sets, the present disclosure is not intended to be so limited. For example, in other embodiments, the cap layer 262 may be formed on only the source region or only the drain region of a given transistor, and not both. As will be apparent in light of this disclosure, the cap layer 262 may be formed to provide increased controllability during contact trench etch and to help suppress contact metal piping, for example.

In some embodiments, the S/D cap layer 262 includes monocrystalline group IV semiconductor material that includes at least one of Si and C. In embodiments employing an S/D cap layer that includes carbon, the S/D cap layer also includes a non-carbon group IV semiconductor material alloyed with the carbon (C), which is referred to herein as “Z:C”, where Z is the non-carbon group IV semiconductor material. For instance, in some such embodiments, the S/D cap layer may include Si alloyed with C, which can be represented as Si:C. Generally, in some embodiments, the cap layer 262 may include Si, Si:C, SiGe, SiGe:C, or Ge:C. In embodiments where the S/D cap layer includes C, the included C concentration (by atomic percentage) may be in the range of 1-20% (or in a suitable subrange, such as in the subrange of 1-2, 1-5, 1-10, 2-5, 2-10, 2-20, 5-10, 5-20, or 10-20%), or any other suitable value or range as will be apparent in light of this disclosure. In embodiments, where the S/D cap layer includes SiGe (with or without also including C), the Ge concentration included in the SiGe cap layer may be relatively lower than the Ge concentration included in the Ge-rich S/D material by at least 5, 10, 15, 20, 25, 30, 35, 40, 45, 50, 55, 60, 65, 70, 75, 80, 85, 90, or 95%, for example. Note that in embodiments where the S/D cap layer includes SiGe and also includes C, such that the S/D cap layer includes SiGe:C, the Ge concentration in the cap layer need not be relatively lower than the Ge concentration in the underlying S/D material, as the included C component in the cap layer can assist in suppressing metal piping (and compensate for the relatively lower Ge concentration), as can be understood based on this disclosure.

In some embodiments, the cap layer 262 may include any suitable dopant type (e.g., n-type, p-type, or undoped/intrinsic) and dopant concentration (e.g., dopant in the range of 1E17-5E22 atoms per cubic cm, where present), as will be apparent in light of this disclosure. In some such embodiments, the cap layer 262 may be doped the same type (e.g., n-type or p-type) relative to the underlying S/D region 260 semiconductor material dopant (e.g., such that they are both n-type doped or both p-type doped). In some embodiments, the cap layer 262 may be relatively heavily doped, and in some cases, degenerately doped with a concentration of at least 1E19, 1E20, 1E21, or 1E22 atoms per cubic cm, which can help reduce S/D contact resistance, as can be understood based on this disclosure. For instance, Si-rich material (such as Si or SiGe with at least 50% Si content) can be effectively doped at relatively higher concentrations compared to Ge-rich material (such as Ge or SiGe with at least 50% Ge content). Thus, in some embodiments, the cap layer 262 may include a higher dopant concentration relative to an underlying Ge-rich S/D region in the amount of at least 1E17, 5E17, 1PE18, 5E18, 1E19, 5E19, 1E20, 5E20, or 1E21 atoms per cubic cm greater dopant concentration, or some other suitable threshold relative value as will be apparent in light of this disclosure. In some embodiments, the cap layer 262 may include a multilayer structure of two or more material layers, for example. In some embodiments, the cap layer 262 may include grading (e.g., increasing and/or decreasing) of the content/concentration of one or more materials in at least a portion of the layer.

In some embodiments, the cap layer 262 may be formed with any suitable thickness T1, such as a thickness in the range of 1-100 nm (or in a suitable subrange, such as 1-5, 1-10, 1-25, 1-50, 2-10, 25, 2-50, 2-100, 5-10, 5-25, 5-50, 5-100, 10-25, 10-50, 10-100, 25-50, 25-100, or 50-100 nm), or any other suitable value or range as will be apparent in light of this disclosure. In some embodiments, the thickness T1 of the cap layer 262 may be inversely related to the concentration (by atomic percentage) of Si and/or C included in the layer. For instance, in embodiments employing relatively high concentrations (by atomic percentage) of Si and/or C in the cap layer, such as C concentrations in the range of 5-20% and/or Si concentrations greater than 75%, a relatively thinner cap layer (e.g., with a thickness in the range of 2-5 nm) may be desired to assist with preventing or reducing contact metal piping, for example. Conversely, in embodiments employing relatively low concentrations (by atomic percentage) of Si and/or C in the cap layer, such as C concentrations less than 5% and/or Si concentrations less than 75%, a relatively thicker cap layer (e.g., with a thickness greater than 5 nm) may be desired to assist with preventing or reducing contact metal piping, for example. As will be apparent in light of this disclosure, during S/D contact formation, the cap layer 26 intermixes with metal material during a germanidation and/or silicidation process, in accordance with some embodiments. Thus, in such embodiments, the cap layer 262 in the contact trench region is at least in part formed into a germanide and/or silicide (depending on the material included in the cap layer) that includes Si and/or C atoms to help suppress contact metal piping from occurring.

Method 100 of FIG. 1 continues with forming 120 etch stop layer 264 on the cap layer 262, thereby forming the example resulting structure of FIG. 2J, in accordance with some embodiments. In some embodiments, the etch stop layer 264 may be formed using any suitable techniques, such as using one or more deposition processes described herein (e.g., CVD, MOCVD, ALD, PVD, MBE), and/or any other suitable processes as will be apparent in light of this disclosure. In some embodiments, the etch stop layer 264 may include any suitable electrical insulator, dielectric, oxide (e.g., silicon oxide), and/or nitride (e.g., silicon nitride) material, as will be apparent in light of this disclosure. In some embodiments, the material of the etch stop layer 264 may be selected based on the material of the subsequently deposited interlayer dielectric (ILD) material 270 formed thereon such that the etch stop layer 264 includes compositionally different insulator material relative to the ILD material 270 to assist with controlling/stopping the contact trench etch based on the relative etch rates between the two different insulator materials for a given etchant. For instance, silicon dioxide may be selected for one of the etch stop layer 264 and the ILD layer 270 while silicon nitride is selected for the other layer to provide relative etch selectivity between the layers. Although the etch stop layer 264 is only shown formed on the S/D regions (and therebetween) in FIG. 2J, it may also be formed on the exposed surfaces of spacers 250 and above the dummy gate stack, for example. In some embodiments, the etch stop layer 264 may be formed with a thickness T2 in the range of 1-500 nm (or any other suitable subrange, such as 1-10, 1-100, 1-250, 10-100, 10-250, or 10-500 nm), or any other suitable value or range as will be apparent in light of this disclosure. In some embodiments, etch stop layer 264 may include a multilayer structure having two or more different material layers.

Method 100 of FIG. 1 continues with performing 122 the final gate stack processing to form the example resulting structure of FIG. 2K, in accordance with some embodiments. As shown in FIG. 2K, the processing in this example embodiment included depositing interlayer dielectric (ILD) layer 270 on the structure of FIG. 2J, followed by planarization and/or polish processing (e.g., CMP) to reveal the dummy gate stack. Note that ILD layer 270 is shown as transparent in the example structure of FIG. 2K to allow for the underlying features to be seen; however, the present disclosure is not intended to be so limited. In some embodiments, the ILD layer 270 may include any suitable electrical insulator, dielectric, oxide (e.g., silicon oxide), and/or nitride (e.g., silicon nitride) material, as will be apparent in light of this disclosure. The gate stack processing, in this example embodiment, continued with removing the dummy gate stack (including dummy gate electrode 244 and dummy gate dielectric 242) to allow for the final gate stack to be formed. Recall that in some embodiments, the formation of the final gate stack, which includes gate dielectric 282 and gate electrode 284, may be performed using a gate first flow (also called up-front hi-k gate). In such embodiments, the final gate stack processing may have been performed at box 114 instead of forming the dummy gate stack. However, in this example embodiment, the gate stack is formed using a gate last flow (also called a replacement gate or replacement metal gate (RMG) process). Regardless of whether gate first or gate last processing is employed, the final gate stack can include gate dielectric 282 and gate electrode 284 as shown in FIG. 2K and described herein. Note that when the dummy gate is removed, the channel region of replacement material fins 230 (that were covered by the dummy gate) are exposed to allow for any desired processing of the channel regions of the fins. Such processing of a given channel region may include various different techniques, such as removing and replacing the channel region with replacement material, doping the channel region as desired, forming the fin into one or more nanowires (or nanoribbons) for a gate-all-around (GAA) transistor configuration, cleaning/polishing the channel region, and/or any other suitable processing as will be apparent in light of this disclosure. For instance, finned channel region 234 is illustrated (which is the channel region of the right-most of the four original finned structures), which may be a portion of replacement material fin 230 or it may have been processed in any suitable manner. Channel region 234′ is shown as including material native to substrate 200 (e.g., in embodiments where the fins formed from substrate 202 were not replaced with replacement material fins 230), in accordance with some embodiments. To provide another example, nanowire channel region 236 (which is the channel region of the left-most of the four original finned structures) may have been formed after the dummy gate was removed and the channel regions of the fins were exposed, by converting the finned structure at that location into the nanowires 236 shown using any suitable techniques, for example. For instance, the original finned channel region may have included a multilayer structure, where one or more of the layers were sacrificial and were selectively etched to remove those sacrificial layers and release the nanowires 236. As shown in FIG. 2K, nanowire channel region 236 includes 2 nanowires (or nanoribbons) in this example case. However, a nanowire (or nanoribbon or GAA) transistor formed using the techniques disclosed herein may include any number of nanowires (or nanoribbons) such as 1, 3, 4, 5, 6, 7, 8, 9, 10, or more, depending on the desired configuration.

As can be understood based on this disclosure, the channel region is at least below the gate stack, in this example embodiment. For instance, in the case of a finned transistor configuration, the channel region may be below and between the gate stack, as the stack is formed on three sides as is known in the art. However, if the transistor device were inverted and bonded to what will be the end substrate, then the channel region may be above the gate. Therefore, in general, the gate and channel relationship may include a proximate relationship (which may or may not include one or more intervening gate dielectric layers and/or other suitable layers), where the gate is near the channel region such that it can exert control over the channel region in some manner (e.g., in an electrical manner), in accordance with some embodiments. Further, in the case of a nanowire (or nanoribbon or GAA) transistor configuration, the gate stack may completely surround each nanowire/nanoribbon in the channel region (or at least substantially surround each nanowire, such as surrounding at least 70, 80, or 90% of each nanowire). In some embodiments, a nanowire or nanoribbon may be considered fin-shaped where the gate stack wraps around each fin-shaped nanowire or nanoribbon in a GAA transistor configuration. Further still, in the case of a planar transistor configuration, the gate stack may simply be above the channel region. In some embodiments, a given channel region may include group IV semiconductor material (e.g., Si, SiGe, Ge) and/or any other suitable material as will be apparent in light of this disclosure. In some embodiments, a given channel region may be doped (e.g., with any suitable n-type and/or p-type dopant) or intrinsic/undoped (or nominally undoped, including dopant concentrations of less than 1E16 atoms per cubic cm, for example), depending on the particular configuration.

Note that S/D regions 260 are adjacent to either side of a corresponding channel region, as can be seen in FIG. 2K, for example. More specifically, the S/D regions 260 are directly adjacent to a corresponding channel region, such that there are no intervening layers between either of the S/D regions and the channel region, in this example embodiment. However, the present disclosure is not intended to be so limited. Also note that the configuration/geometry of a transistor formed using the techniques described herein may primarily be described based on the shape/configuration of the respective channel region of that transistor, for example. For instance, a nanowire (or nanoribbon or GAA) transistor may be referred to as such because it includes one or more nanowires (or nanoribbons) in the channel region of that transistor. However, the transistor type (e.g., MOSFET, TFET, FFFET, or other suitable type) may be described based on the doping and/or operating scheme of the source, channel, and drain regions, and thus those respective regions may be used to determine the type or classification of a given transistor, for example. For instance, MOSFET and TFET transistors may be structurally very similar (or the same), but they include different doping schemes (e.g., source-drain doping schemes for MOSFET of p-p or n-n versus p-n or n-p for TFET).

Continuing with performing 122 final gate stack processing, after the dummy gate has been removed and any desired channel region processing has been performed, the final gate stack can then be formed, in accordance with some embodiments. In this example embodiment, the final gate stack includes gate dielectric 282 and gate electrode 284, as shown in FIG. 2K. The gate dielectric 282 may include, for example, any suitable oxide (such as silicon dioxide), high-k gate dielectric material, and/or any other suitable material as will be apparent in light of this disclosure. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. In some embodiments, an annealing process may be carried out on the gate dielectric 282 to improve its quality when high-k material is used. The gate electrode 284 may include a wide range of materials, such as polysilicon or various suitable metals or metal alloys, such as aluminum (Al), tungsten (W), titanium (Ti), tantalum (Ta), copper (Cu), titanium nitride (TiN), or tantalum nitride (TaN), for example. In some embodiments, gate dielectric 282 and/or gate electrode 284 may include a multilayer structure of two or more material layers, for example. In some embodiments, gate dielectric 282 and/or gate electrode 284 may include grading (e.g., increasing and/or decreasing) of the content/concentration of one or more materials in at least a portion of the feature(s). Additional layers may be present in the final gate stack, in some embodiments, such as one or more work function layers or other suitable layers, for example. Note that although gate dielectric 282 is only shown below gate electrode284 in the example embodiment of FIG. 2K, in other embodiments, the gate dielectric 282 may also be present on one or both sides of gate electrode284, such that the gate dielectric 282 may also be between the gate electrode 284 and one or both of spacers 250, for example. Numerous different gate stack configurations will be apparent in light of this disclosure.

Method 100 of FIG. 1 continues with performing 124 S/D contact processing to form the example resulting structure of FIG. 2P, in accordance with some embodiments. In some embodiments, contact processing 124 may first include forming S/D contact trenches 290 above the S/D regions 260, as shown in FIG. 2L. In some such embodiments, the contact trenches 290 may be formed using any suitable techniques, such as performing one or more wet and/or dry etch processes to remove portions of ILD layer 270 as shown, and/or any other suitable processing as will be apparent in light of this disclosure. Such etch processing may be referred to herein as the S/D contact trench etch processing, or simply, the contact trench etch processing or contact trench etch. Further, in some such embodiments, the ILD material 270 may first be patterned such that areas that are not to be removed via the contact trench etch processing are masked off, for example. As shown in the example structure of FIG. 2L, the etch stop layer 264 was completely consumed/removed during the contact trench etch processing, resulting in the cap layer 262 being exposed in the contact trench 290 locations. Such processing may include two different etch processes to remove the ILD material 270 in the contact trench 290 locations and then remove the etch stop layer 264 from the contact trench 290 locations, for example. However, in some cases, a single etch process may remove the ILD material 270 and the etch stop layer 264 as can be understood based on this disclosure. Regardless, the etch stop layer 264 can be used to protect and/or preserve the cap layer 262 during the contact trench etch processing, as can be understood based on this disclosure.

Continuing from the example structure of FIG. 2L to the example structure of FIG. 2M, S/D contact processing 124 included forming metal layer 291 in contact trenches 290 for the purpose of forming germanidation and/or silicidation with cap layer 262, in accordance with some embodiments. For example, metal layer 291 may include any suitable metal or metal alloy, such as nickel, nickel-platinum, cobalt, and/or titanium, to provide a few examples. In some embodiments, metal layer 291 may include one or more other metals, such as at least one of zirconium (Zr), ruthenium (Ru), niobium (Nb), rhodium (Rh), palladium (Pd), hafnium (Hf), and scandium (Sc). In some such embodiments, the one or more other metals may be alloyed with, for example, nickel or nickel-platinum. In some embodiments, the metal layer 291 may be deposited in contact trenches using any suitable techniques (e.g., CVD, PVD, ALD). Note that although metal layer 291 is only shown in contact trenches 290 in the example structure of FIG. 2M, metal layer 291 may have been formed on the entirety of the structure of FIG. 2L, such that metal layer 291 also forms on ILD material 270. However, the metal layer 291 was not shown elsewhere for ease of illustration. Also note that the gate stack may include an insulator hardmask over it during the deposition of metal layer 291, to allow for such processing and subsequent removal of metal layer 291 therefrom.

Continuing from the example structure of FIG. 2M to the example structure of FIG. 2N, after the metal layer 291 has been formed in contact trenches 290, the S/D contact processing 124 includes one or more annealing processes performed to form metal-semiconductor compound layer 292 that includes the metal from metal layer 291 and also includes the semiconductor material included in cap layer 262, in accordance with some embodiments. In some embodiments, compound layer 292 may be considered a germanide and/or silicide layer, as it may include germanide, such as where cap layer 262 includes Ge and/or where a portion of the material of the Ge-rich S/D 260 becomes a part of the intermixed compound layer, and/or it may include silicide, such as where cap layer 262 includes Si and/or where a portion of the material of Ge-rich S/D 260 becomes a part of the intermixed compound layer and that Ge-rich S/D includes SiGe. For instance, in an example embodiment where cap layer 262 includes SiGe and the metal layer 291 includes nickel (Ni), the resulting compound layer 292 formed from the annealing process(es) would be nickel germanosilicide (NiSiGe). In another example embodiment, where cap layer 262 includes SiGe and the metal layer 291 includes nickel-platinum (NiPt), the resulting compound layer 292 formed from the annealing process(es) would be nickel-platinum germanosilicide (NiPtSiGe). In yet another example embodiment, where cap layer 262 includes Ge:C and the metal layer 291 includes Ni, the resulting compound layer 292 formed from the annealing process(es) would be nickel germanide (NiGe) with carbon atoms intermixed into the compound layer 292. In yet another example embodiment, where cap layer 262 includes Si:C and the metal layer 291 includes cobalt (Co), the resulting compound layer 292 formed from the annealing process(es) would be cobalt silicide (CoSi) with carbon atoms intermixed into the compound layer 292.

Continuing from the example structure of FIG. 2N to the example structure of FIG. 20, after metal-semiconductor compound layer 292 has been formed, the S/D contact processing 124 includes selectively etching metal layer 291 relative to compound layer 292, in accordance with some embodiments. In some such embodiments, any suitable selective etch techniques may be utilized to remove the remaining material of metal layer 291 that was not converted to compound layer 292, while retaining compound layer 292 (at least in part) in the contact trench 290, for example. As shown in FIG. 20, the metal-semiconductor compound layer 292 is present above each S/D region 260 to, for example, improve contact resistance. As can be understood based on this disclosure, the presence of Si (or a relatively higher concentration of Si, where the corresponding S/D region includes SiGe) and/or C in compound layer 292 will help suppress continuous reaction of the metal included in layer 291 (and thus, what is then included in compound layer 292), where such continuous reaction could result in undesired metal piping. Further, in some cases, the compound layer 292 will help suppress the reaction of metal included in contact 293 from diffusing down to the S/D region 260 and also help prevent metal piping from forming.

Continuing from the example structure of FIG. 20 to the example structure of FIG. 2P, the S/D contact processing 124 includes forming S/D contacts 293 above respective S/D regions 260, in accordance with some embodiments. In the example structure of FIG. 2P, it can be understood that S/D contacts 293 are electrically connected to S/D regions 260 but need not be in physical contact with those regions 260 as the compound layer 292 and/or the cap layer 262 may be completely between the S/D contacts 293 and the respective S/D regions 260, for example. However, in some embodiments, at least a portion of S/D contacts 293 may be in physical contact with S/D regions 260. In some embodiments, S/D contacts 293 may be formed using any suitable techniques, such as depositing metal or metal alloy (or other suitable electrically conductive material) in contact trenches 290 and on compound layer 292. In some embodiments, S/D contacts 293 may include aluminum or tungsten, although any suitable conductive metal or alloy can be used, such as silver, nickel-platinum, or nickel-aluminum, for example. In some embodiments, S/D contacts 293 may include one or more other metals, such as at least one of zirconium (Zr), ruthenium (Ru), niobium (Nb), rhodium (Rh), palladium (Pd), hafnium (Hf), and scandium (Sc). In some embodiments, one or more of the S/D contacts 293 may include a resistance reducing metal and a contact plug metal, or just a contact plug, for instance. Example contact resistance reducing metals include, for instance, nickel, aluminum, titanium, gold, gold-germanium, nickel-platinum, or nickel aluminum, and/or other such resistance reducing metals or alloys. Example contact plug metals include, for instance, aluminum, copper, nickel, platinum, titanium, or tungsten, or alloys thereof, although any suitably conductive contact metal or alloy may be used. In some embodiments, additional layers may be present in the S/D contact regions, such as adhesion layers (e.g., titanium nitride) and/or liner or barrier layers (e.g., tantalum nitride), if so desired.

FIG. 3 illustrates an example cross-sectional view along the plane A-A in FIG. 2P, in accordance with some embodiments. The cross-sectional view of FIG. 3 is provided to assist in illustrating different features of a portion of the structure of FIG. 2P. Therefore, the previous relevant description with respect to each similarly numbered feature is equally applicable to FIG. 3. However, note that the dimensions of the features shown in FIG. 3 may differ relative to the features in FIG. 2P, for ease of illustration. Also note that some variations occur between the two structures, such as the shape of spacers 250 and the shape of finned channel region 234, for example. Further note that the portion of the structure where S/D contact trenches 290 were formed is indicated on the left side of FIG. 3, as can be understood based on this disclosure. As can be understood based on FIG. 3, metal-semiconductor compound layer 292 extends into the original contact trench 290, as the metal layer 291 was deposited in that original contact trench 290 and then annealed to intermix the metal with the semiconductor material of cap layer 262. Thus, in this example embodiment, the resulting compound layer 292 is relatively thicker (at least in the vertical Y-axis direction) than the original thickness of cap layer 262 as shown. However, the present disclosure is not intended to be so limited, as the compound layer 292 may include a thickness that is the same as, or even less than, the original thickness of cap layer 262 (e.g., where metal from the metal layer 291 is only driven into the cap layer at that contact trench location and/or where the etch to remove the metal layer 291 relative to the compound layer 292 results in a portion of the compound layer 292 being removed as well). Note that compound layer 292 is between a given S/D region 260 and the corresponding S/D contact 293, such that compound layer 292 may be considered an intervening layer. More specifically, in this example embodiment, the compound layer 292 is only between and completely between a given S/D region 260 and the corresponding S/D contact 293. However, the present disclosure is not intended to be so limited. For instance, the compound layer 292 need not be completely between a given S/D region 260 and the corresponding contact 293, for example. As is also shown in FIG. 3, the cap layer 262 is present on portions of the S/D regions 260 not exposed by the contact trench 290, such that detection of the use of cap layer 262 may be performed via observation of metal-semiconductor compound layer 292 and/or the remainder of cap layer 262, for example.

In some embodiments, the length of gate 284 (e.g., the dimension between spacers 250 in the Z-axis direction), which is indicated as Lg, may be any suitable length as will be apparent in light of this disclosure. For instance, in some embodiments, the gate length may be in the range of 3-100 nm (e.g., 3-10, 3-20, 3-30, 3-50, 5-10, 5-20, 5-30, 5-50, 5-100, 10-20, 10-30, 10-50, 10-100, 20-30, 20-50, 20-100, or 50-100 nm), or any other suitable value or range as will be apparent in light of this disclosure. In some embodiments, the gate length may be less than a given threshold, such as less than 100, 50, 45, 40, 35, 30, 25, 20, 15, 10, 8, or 5 nm, or less than some other suitable threshold as will be apparent in light of this disclosure. In some embodiments, the techniques enable maintaining a desired device performance when scaling to such low thresholds, such as sub-50, sub-40, sub-30, or sub-20 nm thresholds, as can be understood based on this disclosure. Further, the techniques described herein may allow the gate length and the effective channel length (dimension between the S/D regions in the Z-axis direction) to be the same or approximately the same, due to the suppression of metal piping from occurring, in accordance with some embodiments. Thus, the effective gate length may approximate the channel length, in some such embodiments, and the techniques described herein can prevent that effective gate length from undesirably shortening due to undesirable metal material diffusing near or into the channel region.

As previously described, the presence of Si (or relatively higher Si) and/or C in compound layer 292 helps suppress metal piping from occurring as it helps prevent the metal in compound layer 292 (and in some cases, the metal in contact 293) from reacting or further reacting with the underlying Ge-rich S/D region 260, such that it helps suppress the metal material from diffusing down into the S/D region 260 and ultimately helps suppress the metal material from diffusing down into the channel region 234. Such additional reaction and/or diffusion of the metal material would generally occur while the compound layer is being formed and during any subsequent processing (such as during back-end processing described below with reference to box 126). As shown in FIG. 3, hypothetical metal piping 294 is provided in dashed lines to illustrate an example undesired scenario where metal piping occurs. In such an example undesired scenario, if cap layer 262 (and compound layer 292) were not employed to suppress the hypothetical metal piping 294, then metal material from compound layer 292 (and possibly from contacts 293) may diffuse down through the S/D region 260 into the channel region 234 as shown, which decreases the effective gate length (such that the gate length Lg is not the true and effective gate length), thereby decreasing control over the channel and degrading device performance. In some such cases, the hypothetical metal piping 294 can cause the transistor device to electrically short, resulting in device failure. Further, in some such cases, the hypothetical metal piping 294 may cause undesired voids in the structure that degrade device performance and can render the device inoperable. Therefore, the S/D cap layer 262 as described herein can be employed to address these issues.

Method 100 of FIG. 1 continues with completing 126 integrated circuit (IC) processing as desired, in accordance with some embodiments. Such additional processing to complete the IC may include back-end or back-end-of-line (BEOL) processing to form one or more metallization layers and/or to interconnect the transistor devices formed during front-end or front-end-of-line (FEOL) processing, for example. Any other suitable processing may be performed, as will be apparent in light of this disclosure. Note that the processes 102-126 of method 100 are shown in a particular order for ease of description. However, one or more of the processes 102-126 may be performed in a different order or may not be performed at all. For example, box 114 is an optional process that need not be performed in embodiments employing a gate first process flow, for example. Numerous variations on method 100 and the techniques described herein will be apparent in light of this disclosure. Recall that the techniques may be used to form a multitude of different transistor types and configurations. Although the techniques are primarily depicted and described herein in the context of employing an S/D cap layer for both of the S/D regions of a given transistor (such as for both of the p-type S/D regions of a p-MOS device), the present disclosure is not intended to be so limited, as the techniques may be used to benefit only one S/D region of a given transistor, and not the other (e.g., may only benefit the p-type S/D region of a TFET device and not the n-type S/D region). Numerous variations and configurations will be apparent in light of the present disclosure.

Example System

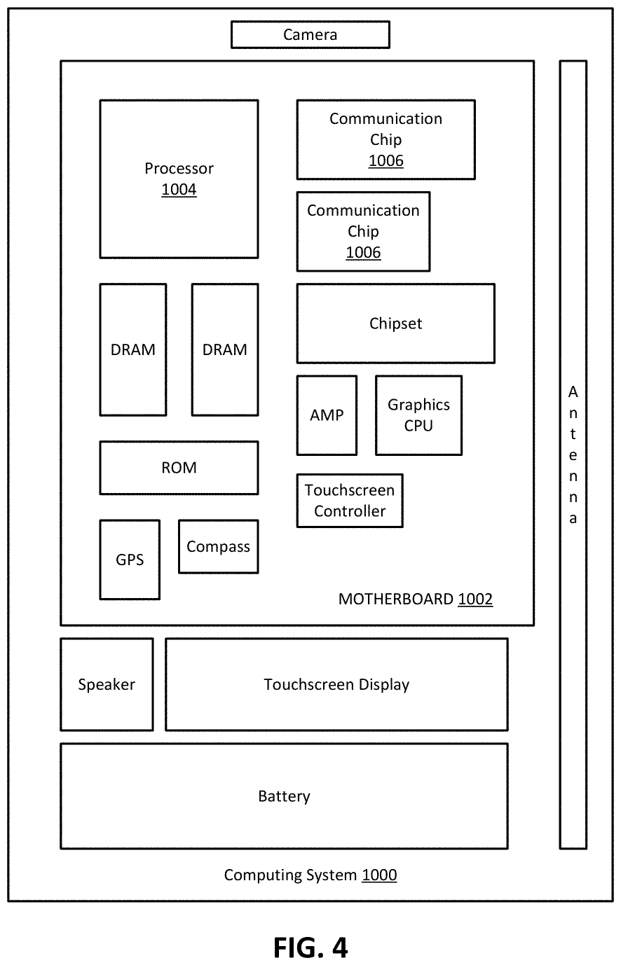

FIG. 4 illustrates a computing system 1000 implemented with integrated circuit structures and/or transistor devices formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1 is an integrated circuit (IC) including at least one transistor, the IC including: a channel region; a gate structure at least above the channel region; a source region adjacent the channel region, the source region including p-type doped monocrystalline germanium; a drain region adjacent the channel region; a contact structure above the source region, the contact structure including at least one metal material; and an intervening layer between the source region and the contact structure, wherein the intervening layer includes at least one metal material and the intervening layer also includes at least one of silicon and carbon.

Example 2 includes the subject matter of Example 1, wherein the metal included in the intervening layer includes nickel.

Example 3 includes the subject matter of Example 2, wherein the metal included in the intervening layer also includes platinum.

Example 4 includes the subject matter of Example 2, wherein the metal included in the intervening layer also includes at least one of zirconium, ruthenium, niobium, rhodium, palladium, hafnium, and scandium.

Example 5 includes the subject matter of any of Examples 1-4, further including a cap layer on one or more top surfaces of the source region in areas where the contact structure is not above the source region, the cap layer including group IV semiconductor material that includes at least one of silicon-rich material and carbon, wherein silicon-rich material includes at least 50% silicon by atomic percentage.

Example 6 includes the subject matter of Example 5, wherein the cap layer includes silicon-rich material.

Example 7 includes the subject matter of Example 5 or 6, wherein the cap layer includes carbon.

Example 8 includes the subject matter of Example 7, wherein the cap layer includes a carbon concentration by atomic percentage of at least 1%.

Example 9 includes the subject matter of any of Examples 5-8, wherein the cap layer includes one of silicon, silicon alloyed with carbon, silicon germanium, silicon germanium alloyed with carbon, and germanium alloyed with carbon.

Example 10 includes the subject matter of any of Examples 5-9, wherein the cap layer has a thickness of 2-100 nanometers.

Example 11 includes the subject matter of any of Examples 5-10, further including: a first insulator material above the cap layer; and a second insulator material between the first insulator material and the cap layer, the second insulator material different than the first insulator material.

Example 12 includes the subject matter of any of Examples 1-11, wherein the intervening layer includes silicon-rich material that includes at least 50% silicon by atomic percentage.

Example 13 includes the subject matter of any of Examples 1-12, wherein the drain region includes p-type doped monocrystalline germanium, and wherein the intervening layer is between the drain region and another contact structure.

Example 14 includes the subject matter of any of Examples 1-13, wherein the source region is raised to a level that is above the channel region, such that the source region is adjacent the gate structure with insulator material between the source region and the gate structure.

Example 15 includes the subject matter of any of Examples 1-14, wherein the at least one transistor includes at least one of the following non-planar configurations: finned, finned field-effect transistor (FinFET), double-gate, tri-gate, nanowire, nanoribbon, and gate-all-around (GAA).

Example 16 includes the subject matter of any of Examples 1-15, wherein the at least one transistor is a p-channel metal-oxide-semiconductor field-effect transistor.

Example 17 is a computing system including the subject matter of any of Examples 1-16.

Example 18 is an integrated circuit (IC) including at least one transistor, the IC including: a channel region including monocrystalline germanium; a gate structure at least above the channel region; a source region adjacent the channel region, the source region including p-type doped monocrystalline germanium; a drain region adjacent the channel region; a contact structure above the source region, the contact structure including at least one metal material; and a cap layer on one or more top surfaces of the source region in areas where the contact structure is not above the source region, the cap layer including monocrystalline group IV semiconductor material that includes at least one of silicon-rich material and carbon, wherein silicon-rich material includes at least 50% silicon by atomic percentage.

Example 19 includes the subject matter of Example 18, further including an intervening layer between the source region and the contact structure, wherein the intervening layer includes at least one metal material and the intervening layer also includes the at least one of silicon and carbon included in the cap layer.

Example 20 includes the subject matter of Example 19, wherein the metal included in the intervening layer includes nickel.

Example 21 includes the subject matter of Example 20, wherein the metal included in the intervening layer also includes platinum.

Example 22 includes the subject matter of Example 20, wherein the metal included in the intervening layer also includes at least one of zirconium, ruthenium, niobium, rhodium, palladium, hafnium, and scandium.

Example 23 includes the subject matter of any of Examples 19-22, wherein the intervening layer includes silicon-rich material that includes at least 50% silicon by atomic percentage.

Example 24 includes the subject matter of any of Examples 18-23, wherein the cap layer includes silicon-rich material.

Example 25 includes the subject matter of any of Examples 18-24, wherein the cap layer includes carbon.

Example 26 includes the subject matter of Example 25, wherein the cap layer includes a carbon concentration by atomic percentage of at least 2%.

Example 27 includes the subject matter of any of Examples 18-26, wherein the cap layer includes one of silicon, silicon alloyed with carbon, silicon germanium, silicon germanium alloyed with carbon, and germanium alloyed with carbon.

Example 28 includes the subject matter of any of Examples 18-27, wherein the cap layer has a thickness of 2-100 nanometers.

Example 29 includes the subject matter of any of Examples 18-28, further including: a first insulator material above the cap layer; and a second insulator material between the first insulator material and the cap layer, the second insulator material different than the first insulator material.

Example 30 includes the subject matter of any of Examples 18-29, wherein the drain region includes p-type doped monocrystalline germanium, and wherein the cap layer is one or more top surfaces of the drain region in areas where another contact structure is not above the drain region.

Example 31 includes the subject matter of any of Examples 18-30, wherein the source region is raised to a level that is above the channel region, such that the source region is adjacent the gate structure with insulator material between the source region and the gate structure.

Example 32 includes the subject matter of any of Examples 18-31, wherein the at least one transistor includes at least one of the following non-planar configurations: finned, finned field-effect transistor (FinFET), double-gate, tri-gate, nanowire, nanoribbon, and gate-all-around (GAA).

Example 33 includes the subject matter of any of Examples 18-32, wherein the at least one transistor is a p-channel metal-oxide-semiconductor field-effect transistor.

Example 34 is a mobile computing system including the subject matter of any of Examples 18-33.

Example 35 is a method of forming an integrated circuit (IC) including at least one transistor, the method including: forming a gate structure at least above a channel region; forming a source region adjacent the channel region, the source region including p-type doped monocrystalline germanium; forming a drain region adjacent the channel region; forming a cap layer on one or more top surfaces of the source region, the cap layer including group IV semiconductor material that includes at least one of silicon-rich material and carbon, wherein silicon-rich material includes at least 50% silicon by atomic percentage; and forming a contact structure above the layer, the contact structure including at least one metal material; wherein forming the contact structure includes forming an intervening layer between the source region and the contact structure, wherein the intervening layer includes at least one metal material and the intervening layer also includes the group IV semiconductor material included in the cap layer.

Example 36 includes the subject matter of Example 35, wherein the cap layer is formed on two top surfaces of the source region.

Example 37 includes the subject matter of Example 35 or 36, further including forming the cap layer on one or more top surfaces of the drain region while forming the cap layer on one or more top surfaces of the source region.

Example 38 includes the subject matter of any of Examples 35-37, wherein the monocrystalline group IV semiconductor material is one of silicon and silicon germanium.

Example 39 includes the subject matter of any of Examples 35-38, wherein the cap layer includes germanium and carbon.

Example 40 includes the subject matter of any of Examples 35-39, wherein the cap layer includes carbon.

Example 41 includes the subject matter of any of Examples 35-39, wherein forming the intervening layer includes depositing a metal material layer in a contact trench and performing one or more anneal processes to intermix metal in the metal material layer with the group IV semiconductor material included in the cap layer.

Example 42 includes the subject matter of Example 41, wherein the intervening layer includes at least one of germanide and silicide material.

Example 43 includes the subject matter of Example 41 or 42, wherein forming the intervening layer further includes selectively etching the metal material layer relative to the intervening layer to remove a portion of the metal material layer that did not intermix with the group IV semiconductor material included in the cap layer, such that the portion of the metal material layer is removed from the contact trench and the intervening layer remains at least in part.

Example 44 includes the subject matter of any of Examples 35-43, wherein a distinct portion of the intervening layer is also between the drain region and another contact structure.

Example 45 includes the subject matter of any of Examples 35-44, further including forming an etch stop layer on the cap layer, the etch stop layer including insulator material.

Example 46 includes the subject matter of Example 45, further including etching an insulator layer above the source region to form a contact trench, the insulator layer including different material than the insulator material included in the etch stop layer, wherein the contact structure is formed in the contact trench.

Example 47 includes the subject matter of any of Examples 35-46, wherein the gate structure is formed using a gate first process, such that the gate structure is formed prior to forming the source region.

Example 48 includes the subject matter of any of Examples 35-46, wherein the gate structure is formed using a gate last process, such that the gate structure is formed after forming the source region.

Example 49 includes the subject matter of any of Examples 35-48, wherein the at least one transistor includes at least one of the following non-planar configurations: finned, finned field-effect transistor (FinFET), double-gate, tri-gate, nanowire, nanoribbon, and gate-all-around (GAA).

Example 50 includes the subject matter of any of Examples 35-49, wherein the at least one transistor is a p-channel metal-oxide-semiconductor field-effect transistor.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1. An integrated circuit (IC) comprising:
a semiconductor region;
a gate structure at least above the semiconductor region;
a source region adjacent the semiconductor region, the source region including p-type doped monocrystalline germanium;
a drain region adjacent the semiconductor region;
a contact structure above the source region, the contact structure including at least one metal material; and
an intervening layer between the source region and the contact structure, wherein the intervening layer includes at least one metal material and the intervening layer also includes at least one of silicon and carbon.

2. The IC of claim 1, wherein the metal included in the intervening layer includes nickel.

3. The IC of claim 2, wherein the metal included in the intervening layer also includes platinum.

4. The IC of claim 2, wherein the metal included in the intervening layer also includes at least one of zirconium, ruthenium, niobium, rhodium, palladium, hafnium, and scandium.

5. The IC of claim 1, further comprising a cap layer on one or more top surfaces of the source region in areas where the contact structure is not above the source region, the cap layer including group IV semiconductor material that includes at least one of silicon-rich material and carbon, wherein silicon-rich material includes at least 50% silicon by atomic percentage.

6. The IC of claim 5, wherein the cap layer includes silicon-rich material.

7. The IC of claim 5, wherein the cap layer includes carbon.

8. The IC of claim 7, wherein the cap layer includes a carbon concentration by atomic percentage of at least 1%.

9. The IC of claim 5, wherein the cap layer includes one of silicon, silicon alloyed with carbon, silicon germanium, silicon germanium alloyed with carbon, and germanium alloyed with carbon.

10. The IC of claim 5, wherein the cap layer has a thickness of 2-100 nanometers.

11. The IC of claim 5, further comprising:
a first insulator material above the cap layer; and
a second insulator material between the first insulator material and the cap layer, the second insulator material different than the first insulator material.

12. The IC of claim 1, wherein the intervening layer includes silicon-rich material that includes at least 50% silicon by atomic percentage.

13. The IC of claim 1, wherein the drain region includes p-type doped monocrystalline germanium, and wherein the intervening layer is between the drain region and another contact structure.

14. The IC of claim 1, wherein the source region is raised to a level that is above the semiconductor region, such that the source region is adjacent the gate structure with insulator material between the source region and the gate structure.

15. The IC of claim 1, wherein the semiconductor region is part of a fin, and the gate structure is on top and side walls of the fin.

16. The IC of claim 1, wherein the semiconductor region includes one or more nanowires or nanoribbons, and the gate wraps around the one or more nanowires or nanoribbons.

17. (canceled)

18. An integrated circuit (IC), comprising:
a non-planar semiconductor region including monocrystalline germanium;
a gate structure on top and sides of the non-planar semiconductor region;
a source region adjacent the non-planar semiconductor region, the source region including p-type doped monocrystalline germanium;
a drain region adjacent the non-planar semiconductor region;
a contact structure above the source region, the contact structure including at least one metal material; and
a cap layer on one or more top surfaces of the source region in areas where the contact structure is not above the source region, the cap layer including monocrystalline group IV semiconductor material that includes at least one of silicon-rich material and carbon, wherein silicon-rich material includes at least 50% silicon by atomic percentage.

19. The IC of claim 18, further comprising an intervening layer between the source region and the contact structure, wherein the intervening layer includes at least one metal material and the intervening layer also includes the at least one of silicon and carbon included in the cap layer.

20. (canceled)

21. The IC of claim 18, wherein the source region is raised to a level that is above the non-planar semiconductor region, such that the source region is adjacent the gate structure with insulator material between the source region and the gate structure.

22. (canceled)

23. A method of forming an integrated circuit (IC), the method comprising:
forming a gate structure at least above a semiconductor region;
forming a source region adjacent the semiconductor region, the source region including p-type doped monocrystalline germanium;
forming a drain region adjacent the semiconductor region;
forming a cap layer on one or more top surfaces of the source region, the cap layer including group IV semiconductor material that includes at least one of silicon-rich material and carbon, wherein silicon-rich material includes at least 50% silicon by atomic percentage; and
forming a contact structure above the layer, the contact structure including at least one metal material;
wherein forming the contact structure includes forming an intervening layer between the source region and the contact structure, wherein the intervening layer includes at least one metal material and the intervening layer also includes the group IV semiconductor material included in the cap layer.

24. (canceled)

25. (canceled)
